(19) United States
(12) Patent Application Publication
(10) Pub. No.: US 2025/0040292 A1
(43) Pub. Date: Jan. 30, 2025

(54) CYLINDER HEAD, TRANSFER AND BONDING SYSTEM INCLUDING THE SAME, AND METHOD FOR DRIVING THE SAME

(71) Applicant: Samsung Display Co., LTD., Yongin-si (KR)

(72) Inventors: Jong Hyup KIM, Yongin-si (KR); Futoshi YOSHIDA, Yongin-si (KR); Jin Pyung LEE, Yongin-si (KR)

(73) Assignee: Samsung Display Co., LTD., Yongin-si (KR)

(21) Appl. No.: 18/771,612

(22) Filed: Jul. 12, 2024

(30) Foreign Application Priority Data
Jul. 28, 2023 (KR) 10-2023-0099017

(51) Int. Cl. H01L 33/00; H01L 21/66

(52) U.S. Cl. CPC H01L 33/005; H01L 22/20

(57) ABSTRACT

A cylinder head, a transfer and bonding system and a method of driving the same to produce a display device that includes light emitting elements provides uniform pressure to light emitting elements during a transfer and bonding process. The cylinder head may include a first bracket accommodating the first transmissive portion; a second transmissive portion spaced apart from the first transmissive portion in a direction by an air layer; a second bracket accommodating the second transmissive portion; and an elastic member surrounding side surfaces of the first bracket and the second bracket, wherein one of the first bracket and the second bracket includes an air path that extends to the air layer.

### CROSS-REFERENCE TO RELATED APPLICATIONS

This application claims priority under 35 U.S.C. 119 from Korean Patent Application No. 10-2023-0099017 filed on Jul. 28, 2023 in the Korean Intellectual Property Office, the entire contents of which are incorporated herein by reference.

### BACKGROUND

### 1. Technical Field

Embodiments of the disclosure relate to a cylinder head, a transfer and bonding system including the same, and a method for driving the same.

### 2. Description of the Related Art

As information technology has developed, importance of a display device, which may be a connection medium between a user and information, has been highlighted. Accordingly, the use of display devices such as a liquid crystal display device, an organic light emitting display device, and the like has been increasing.

For example, a display panel may be formed by transferring a light emitting element onto a substrate on which a thin film transistor is formed, and a display device including the display panel formed as above may be used.

As described above, in a process of manufacturing the display panel, a process of bonding the light emitting element may be performed to reduce electrical resistance in an area in which the thin film transistor and the light emitting element may be extended.

### SUMMARY

The disclosure has been made in an effort to provide a cylinder head, a transfer and bonding system including the same, and a method for driving the same that may provide uniform pressure to a light emitting element during a transfer and a bonding process of a light emitting element.

Embodiments of the disclosure provide a cylinder head that may include a first transmissive portion including at least one first air path extending to an air layer; a first bracket accommodating the first transmissive portion; a second transmissive portion spaced apart from the first transmissive portion in a direction by the air layer; a second bracket accommodating the second transmissive portion; and an elastic member surrounding side surfaces of the first bracket and the second bracket, wherein one of the first bracket and the second bracket includes a second air path extending to the air layer.

The elastic member may be stretched in the direction by air introduced through the second air path.

The elastic member may contract in the direction in case that air is expelled from the cylinder head through the second air path.

The cylinder head may further include a first fastening portion configured to surround the elastic member and to fix the elastic member to a side surface of the first bracket; and a second fastening portion configured to surround the elastic member and to fix the elastic member to a side surface of the second bracket.

The cylinder head may further include a first buffer member disposed between the first transmissive portion and the first bracket and surrounding a side surface of the first transmissive portion; and a second buffer member disposed between the second transmissive portion and the second bracket and surrounding a side surface of the second transmissive portion.

The first bracket may include an alignment mark that overlaps the first transmissive portion and the second transmissive portion.

A volume of the air layer may vary.

The at least one first air path may include a plurality of first air paths; and the plurality of first air paths may be arranged in a lattice form.

The second air path may extend to an air pump configured to inject or discharge air.

Embodiments of the disclosure may provide a transfer and bonding system, that may include a cylinder head; an imaging device configured to obtain an image in a direction; and a heat source configured to apply heat to the cylinder head, wherein the cylinder head may include a first transmissive portion including a first air path extending to an air layer; a first bracket accommodating the first transmissive portion; a second transmissive portion spaced apart from the first transmissive portion in the direction by the air layer; a second bracket accommodating the second transmissive portion; and an elastic member surrounding side surfaces of the first bracket and the second bracket, and wherein one of the first bracket and the second bracket includes a second air path extending to the air layer.

The transfer and bonding system may further include a transfer substrate that includes a carrier substrate; and a plurality of light emitting elements coupled to the carrier substrate, wherein the carrier substrate may be in contact with the first transmissive portion.

The transfer and bonding system may further include a thin film transistor substrate including a thin film transistor layer, wherein a position of the cylinder head may be adjusted based on the image obtained of a pattern of the thin film transistor substrate.

The first bracket may include an alignment mark that overlaps the first transmissive portion and the second transmissive portion, and wherein a position of the cylinder head may be adjusted based on the image obtained by the imaging device of the alignment mark.

The carrier substrate may be coupled to the cylinder head in case that air is discharged from the second air path to an outside, the carrier substrate may be separated from the cylinder head in case that air is introduced into the second air path from an outside.

The heat source may irradiate a laser onto the first transmissive portion and the second transmissive portion.

Embodiments of the disclosure provide a driving method, including: providing a the cylinder head that may include a first transmissive portion including a first air path extending to an air layer; a first bracket accommodating the first transmissive portion; a second transmissive portion spaced apart from the first transmissive portion in a direction by the air layer; a second bracket accommodating the second transmissive portion; and an elastic member surrounding side surfaces of the first bracket and the second bracket, and one of the first bracket and the second bracket may include a second air path extending to the air layer, providing a transfer substrate that includes a carrier substrate coupled to a plurality of light emitting elements, providing a thin film transistor substrate that includes a thin film transistor layer, moving the cylinder head towards the a transfer substrate; discharging air from the cylinder head through the second air path to couple the transfer substrate to the first transmissive portion of the cylinder head; moving the cylinder head that is coupled to the transfer substrate towards a thin film transistor substrate; injecting air into the cylinder head through the second air path to press the first transmissive portion of the cylinder head against the transfer substrate; discharging the air from the cylinder head through the second air path to couple the carrier substrate to the first transmissive portion of the cylinder head; and injecting the air into the cylinder head via the second air path to separate the carrier substrate from the first transmissive portion of the cylinder head.

The moving of the cylinder head that is coupled to the transfer substrate towards the thin film transistor substrate may include obtaining an image of the thin film transistor substrate; detecting a pattern in the thin film transistor substrate from the image; and adjusting a position of the cylinder head based on the detected pattern.

The moving of the cylinder head coupled to the transfer substrate towards the thin film transistor substrate may include obtaining an image of an alignment mark of the cylinder head; and adjusting a position of the cylinder head based on the image.

The plurality of light emitting elements may be micro light emitting diodes.

The injecting of the air into the cylinder head to press the first transmissive portion of the cylinder head against the transfer substrate may include irradiating the thin film transistor substrate with a laser that transmits through the first transmissive portion and the second transmissive portion.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a top plan view of a display device according to embodiments of the disclosure;

FIG. 2 illustrates an example of a pixel of FIG. 1;

FIG. 3 illustrates another example of a pixel of FIG. 1;

FIG. 4 illustrates a schematic cross-sectional view of an example of a display device taken along line A-A′ of FIG. 3;

FIG. 5 illustrates a perspective view of a tiled display device including a plurality of display devices according to embodiments of the disclosure;

FIG. 6 illustrates an enlarged schematic diagram of an area AR1 of FIG. 5 in detail;

FIG. 7 illustrates a schematic cross-sectional view of an example of a tiled display device taken along line B-B′ of FIG. 6;

FIG. 8 illustrates an enlarged schematic diagram of an area AR2 of FIG. 5 in detail;

FIG. 9 illustrates a schematic cross-sectional view of an example of a tiled display device taken along line F-F′ of FIG. 8;

FIG. 10 illustrates a schematic block diagram of a tiled display device according to embodiments of the disclosure;

FIG. 11 schematically illustrates a transfer process of a light emitting element;

FIG. 12 illustrates an example of a backplane substrate to which a light emitting element is transferred;

FIG. 13 illustrates a perspective view of a cylinder head according to embodiments of the disclosure;

FIG. 14 illustrates a schematic cross-sectional view of the cylinder head of FIG. 13 taken along line X-X′;

FIG. 15A illustrates a state in which air is discharged from the cylinder head of FIG. 13 as an example;

FIG. 15B illustrates a state in which air is injected into the cylinder head of FIG. 13 as an example;

FIG. 16 illustrates a top view of the cylinder head of FIG. 13; and

FIGS. 17 to 26 illustrate a method for driving a transfer and bonding system according to embodiments of the disclosure, respectively.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the inventive concepts. Further, the blocks, parts, and/or modules of some embodiments may be physically combined into more complex blocks, parts, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in detail with reference to the accompanying drawings.

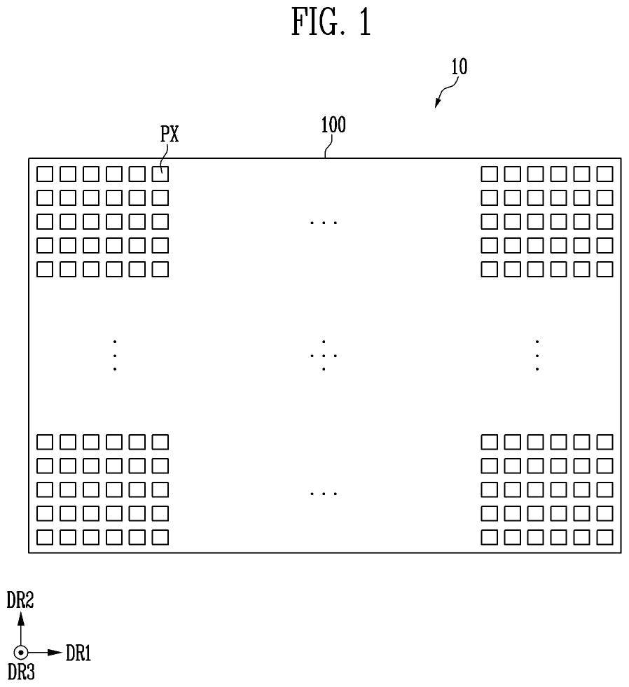

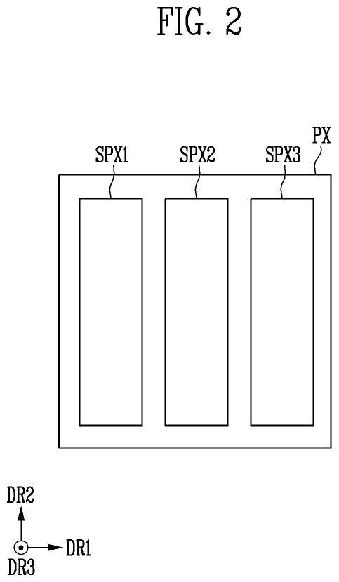

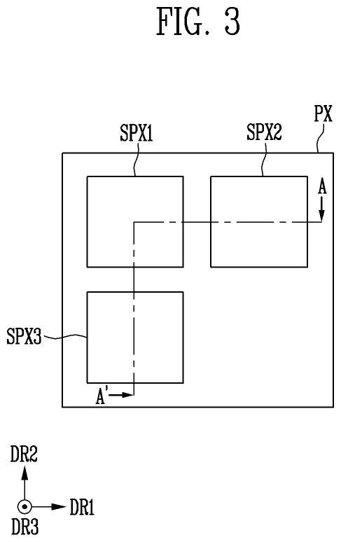

FIG. 1 illustrates a top plan view of a display device 10 according to embodiments of the disclosure. FIG. 2 illustrates of an example of a pixel PX of FIG. 1. FIG. 3 illustrates another example of a pixel PX of FIG. 1.

Referring to FIG. 1, the display device 10 may be a device for displaying a moving image or a still image, and may be used as a display screen of a portable electronic device such as a mobile phone, a smart phone, a tablet personal computer (PC), a smart watch, a watch phone, a mobile communication terminal, an electronic note, an electronic book, a portable multimedia players (PMP), a navigation device, and an ultra mobile PC (UMPC), and may be used as display screens of various products such as a television set, a laptop computer, a monitor, a billboard, an Internet of Things (IoT).

A display panel 100 may be formed as an approximately flat surface having a rectangular shape having a long side of a first direction DR1 and a short side of a second direction DR2 intersecting the first direction DR1. A corner at which the long side of the first direction DR1 and the short side of the second direction DR2 meet may be rounded to have a curvature (e.g., predetermined or selectable curvature) or may be formed to have a right angle. The approximately flat shape of the display panel 100 may not be limited to a quadrangular shape, and may be formed to have another polygonal, circular, or elliptical shape. The display panel 100 may be formed to be approximately flat, but may not be limited thereto. For example, the display panel 100 may include curved portions that may be formed at left and right ends and have a constant curvature or a variable curvature. The display panel 100 may be flexibly formed to be bent, curved, folded, or rolled.

The display panel 100 may further include pixels PX, scan lines extending in the first direction DR1, and data lines extending in the second direction DR2, to display an image. The pixels PX may be arranged in a matrix format in the first direction DR1 and the second direction DR2. The first direction DR1 and the second direction DR2 may be directions orthogonal to each other (for example, an x-axis in a horizontal direction and a y-axis in a vertical direction), but may not be limited thereto.

The pixel PX may include multiple sub-pixels SPX1, SPX2, and SPX3 as shown in FIG. 2 and FIG. 3. FIG. 2 and FIG. 3 illustrate that the pixel PX includes three sub-pixels SPX1, SPX2, and SPX3, that is, a first sub-pixel SPX1, a second sub-pixel SPX2, and third sub-pixel SPX3, but embodiments of the disclosure may not be limited thereto.

Each of the first sub-pixel SPX1, the second sub-pixel SPX2, and the third sub-pixel SPX3 may be electrically connected to one of multiple data lines, and may be electrically connected to at least one of multiple scan lines.

Each of the first sub-pixel SPX1, the second sub-pixel SPX2, and the third sub-pixel SPX3 may have a rectangular, square, or rhombus planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 2. Each of the first sub-pixel SPX1, the second sub-pixel SPX2, and the third sub-pixel SPX3 may have a square or rhombus planar shape including sides having a same length in the first direction DR1 and the second direction DR2 as shown in FIG. 3.

As shown in FIG. 2, the first sub-pixel SPX1, the second sub-pixel SPX2, and the third sub-pixel SPX3 may be arranged in the first direction DR1.

One of the second sub-pixel SPX2 and the third sub-pixel SPX3 and the first sub-pixel SPX1 may be arranged in the first direction DR1, and another thereof and the first sub-pixel SPX1 may be arranged in the second direction DR2. For example, as shown in FIG. 3, the first sub-pixel SPX1 and the second sub-pixel SPX2 may be arranged in the first direction DR1, and the first sub-pixel SPX1 and the third sub-pixel SPX3 may be arranged in the second direction DR2. One of the first sub-pixel SPX1 and the third sub-pixel SPX3 and the second sub-pixel SPX2 may be arranged in the first direction DR1, and another thereof and the second sub-pixel SPX2 may be arranged in the second direction DR2. One of the first sub-pixel SPX1 and the second sub-pixel SPX2 and the third sub-pixel SPX3 may be arranged in the first direction DR1, and another thereof and the third sub-pixel SPX3 may be arranged in the second direction DR2.

The first sub-pixel SPX1 may emit first light, the second sub-pixel SPX2 may emit second light, and the third sub-pixel SPX3 may emit third light. Here, the first light may be light of a red wavelength band, the second light may be light of a green wavelength band, and the third light may be light of a blue wavelength band. The red wavelength band may be a wavelength band of about 600 nm (nanometer) to 750 nm, the green wavelength band may be a wavelength band of about 480 nm to 560 nm, and the blue wavelength band may be a wavelength band of about 370 nm to 460 nm, but embodiments of the disclosure may not be limited thereto.

Each of the first sub-pixel SPX1, the second sub-pixel SPX2, and the third sub-pixel SPX3 may be a light emitting element emitting light, and may include an inorganic light emitting element including an inorganic semiconductor. For example, the inorganic light emitting element may be a flip chip type micro light emitting diode (micro LED; hereinafter also referred to as a micro LED), but embodiments of the disclosure may not be limited thereto.

As shown in FIG. 2 and FIG. 3, the first sub-pixel SPX1, the second sub-pixel SPX2, and the third sub-pixel SPX3 may have substantially a same area, but embodiments of the disclosure may not be limited thereto. At least one of the area of the first sub-pixel SPX1, the area of the second sub-pixel SPX2, and the area of the third sub-pixel SPX3 may be different from another one thereof. Two of the first sub-pixel SPX1, the second sub-pixel SPX2, and the third sub-pixel SPX3 may have substantially a same area, and another thereof may be different from the two. The first sub-pixel SPX1, the second sub-pixel SPX2, and the third sub-pixel SPX3 may have different areas from each other.

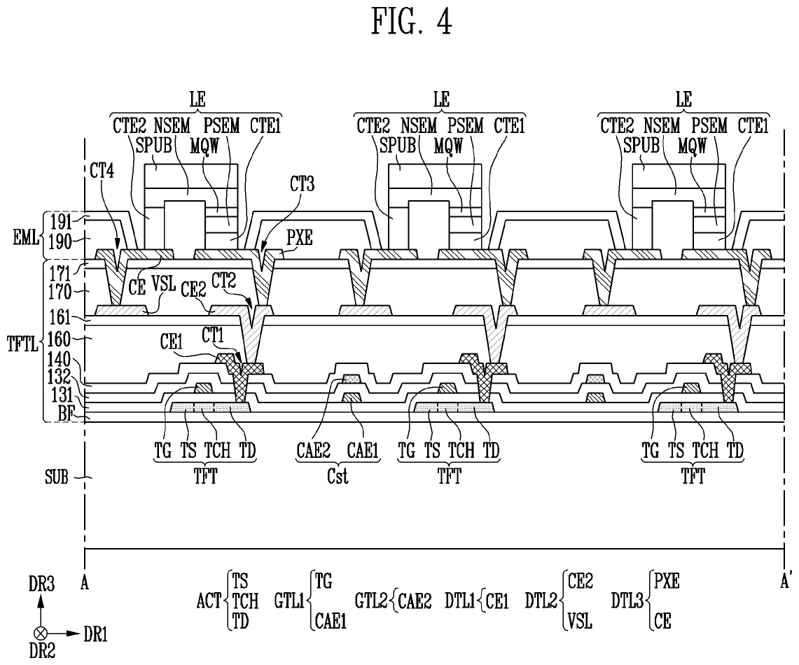

FIG. 4 illustrates a schematic cross-sectional view of an example of a display device taken along line A-A′ of FIG. 3.

Referring to FIG. 4, a thin film transistor layer TFTL may be disposed on a substrate SUB. The thin film transistor layer TFTL may be a layer in which thin film transistors (TFT) may be formed.

The thin film transistor layer TFTL may include an active layer ACT, a first gate layer GTL1, a second gate layer GTL2, a first data metal layer DTL1, and a second data metal layer DTL2. The thin film transistor layer TFTL may include a buffer film BF, a first gate insulating film 131, a second gate insulating film 132, an interlayer insulating film 140, a first planarization film 160, a first insulating film 161, a second planarization film 170, a second insulating film 171, and the like.

The substrate SUB may be a base substrate or a base member for supporting the display device 10 (see FIG. 1). The substrate SUB may be a rigid substrate made of a glass material. The substrate SUB may be a flexible substrate that may be bendable, foldable, or rollable. The substrate SUB may include an insulating material such as a polymer resin such as polyimide (PI).

The buffer film BF may be disposed on a surface of the substrate SUB. The buffer film BF may be a film for preventing penetration of air or moisture. The buffer film BF may be formed of multiple inorganic films that may be alternately stacked on each other. For example, the buffer film BF may be formed as a multifilm in which at least one inorganic film of a silicon nitride layer, a silicon oxynitride layer, a silicon oxide layer, a titanium oxide layer, and an aluminum oxide layer may be alternately stacked on each other. The buffer film BF may be omitted.

The active layer ACT may be disposed on the buffer film BF. The active layer ACT may include a silicon semiconductor such as polycrystalline silicon, single crystal silicon, low-temperature polycrystalline silicon, and amorphous silicon, or an oxide semiconductor.

The active layer ACT may include a channel TCH, a first electrode TS, and a second electrode TD of the thin film transistor TFT. The channel TCH of the thin film transistor TFT may be an area overlapping the gate electrode TG of the thin film transistor TFT in a third direction DR3 that may be a thickness direction of the substrate SUB. The first electrode TS of the thin film transistor TFT may be disposed at a side of the channel TCH, and the second electrode TD may be disposed at another side of the channel TCH. The first electrode TS and the second electrode TD of the thin film transistor TFT may be areas that do not overlap the gate electrode TG in the third direction DR3. The first electrode TS and the second electrode TD of the thin film transistor TFT may be areas in which a semiconductor (for example, a silicon semiconductor, an oxide semiconductor, or the like) may be doped with ions to have conductivity.

The first gate insulating film 131 may be disposed on the active layer ACT. The first gate insulating film 131 may be formed as an inorganic film, for example, a silicon nitride layer, a silicon oxynitride layer, a silicon oxide layer, a titanium oxide layer, or an aluminum oxide layer.

The first gate layer GTL1 may be disposed on the first gate insulating film 131. The first gate layer GTL1 may include the gate electrode TG and a first capacitor electrode CAE1 of capacitor Cst. The first gate layer GTL1 may be formed as a single layer or a multilayer that may be made of one of molybdenum (Mo), aluminum (Al), chromium (Cr), gold (Au), titanium (Ti), nickel (Ni), neodymium (Nd), and copper (Cu) or an alloy thereof.

The second gate insulating film 132 may be disposed on the first gate layer GTL1. The second gate insulating film 132 may be formed as an inorganic film, for example, a silicon nitride layer, a silicon oxynitride layer, a silicon oxide layer, a titanium oxide layer, or an aluminum oxide layer.

The second gate layer GTL2 may be disposed on the second gate insulating film 132. The second gate layer GTL2 may include a second capacitor electrode CAE2. The second gate layer GTL2 may be formed as a single layer or a multilayer that may be made of one of molybdenum (Mo), aluminum (Al), chromium (Cr), gold (Au), titanium (Ti), nickel (Ni), neodymium (Nd), and copper (Cu) or an alloy thereof.

The interlayer insulating film 140 may be disposed on the second gate layer GTL2. The interlayer insulating film 140 may be formed as an inorganic film, for example, a silicon nitride layer, a silicon oxynitride layer, a silicon oxide layer, a titanium oxide layer, or an aluminum oxide layer.

The first data metal layer DTL1 including a first connection electrode CE1 may be disposed on the interlayer insulating film 140. The first data metal layer DTL1 may be formed as a single layer or a multilayer that may be made of one of molybdenum (Mo), aluminum (Al), chromium (Cr), gold (Au), titanium (Ti), nickel (Ni), neodymium (Nd), and copper (Cu) or an alloy thereof.

The first connection electrode CE1 may be connected (for example, electrically connected) through a first contact hole CT1 penetrating the second gate insulating film 132 and the interlayer insulating film 140.

The first planarization film 160 may be formed on the first data metal layer DTL1 for flattening a step caused by the active layer ACT, the first gate layer GTL1, the second gate layer GTL2, and the first data metal layer DTL1. The first planarization film 160 may be formed as an organic film including an acryl resin, an epoxy resin, a phenolic resin, a polyamide resin, a polyimide resin, and the like.

The first insulating film 161 may be disposed on the first planarization film 160. The first insulating film 161 may be formed as an inorganic film, for example, a silicon nitride layer, a silicon oxynitride layer, a silicon oxide layer, a titanium oxide layer, or an aluminum oxide layer.

The second data metal layer DTL2 may be formed on the first insulating film 161. The second data metal layer DTL2 may include the second connection electrode CE2 and a first power wire VSL. The second connection electrode CE2 may be electrically connected to the first connection electrode CE1 through a second contact hole CT2 penetrating the first insulating film 161 and the first planarization film 160. The second data metal layer DTL2 may be formed as a single layer or a multilayer that may be made of one of molybdenum (Mo), aluminum (Al), chromium (Cr), gold (Au), titanium (Ti), nickel (Ni), neodymium (Nd), and copper (Cu) or an alloy thereof.

The second planarization film 170 may be formed on the second data metal layer DTL2 to flatten a step. The second planarization film 170 may be formed as an organic film including an acryl resin, an epoxy resin, a phenolic resin, a polyamide resin, a polyimide resin, and the like.

The second insulating film 171 may be disposed on the second planarization film 170. The second insulating film 171 may be formed as an inorganic film, for example, a silicon nitride layer, a silicon oxynitride layer, a silicon oxide layer, a titanium oxide layer, or an aluminum oxide layer.

A light emitting element layer EML may be disposed on the second insulating film 171. The light emitting element layer EML includes a pixel electrode PXE, a common electrode CE, and a light emitting element LE. A third data metal layer DTL3 may include the pixel electrode PXE and the common electrode CE. Each of the first sub-pixel SPX1, the second sub-pixel SPX2, and the third sub-pixel SPX3 described above includes the light emitting element LE electrically connected to the pixel electrode PXE and the common electrode CE. The pixel electrode PXE may be one (for example, an anode electrode) of an anode electrode and a cathode electrode of the light emitting element LE. The common electrode CE may be the other (for example, a cathode electrode) of an anode electrode and a cathode electrode of the light emitting element LE.

The pixel electrode PXE and the common electrode CE may be disposed on the second insulating film 171. The pixel electrode PXE may be connected (for example, electrically connected) to the second connection electrode CE2 through a third contact hole CT3 penetrating the second insulating film 171 and the second planarization film 170. Accordingly, the pixel electrode PXE may be electrically connected to the first electrode TS or the second electrode TD of the thin film transistor TFT through the first connection electrode CE1 and the second connection electrode CE2. Accordingly, a pixel voltage or an anode voltage controlled by the thin film transistor TFT may be applied to the pixel electrode PXE.

The common electrode CE may be electrically connected to the first power wire VSL through a fourth contact hole CT4 penetrating the second insulating film 171 and the second planarization film 170. Accordingly, a first power voltage of the first power wire VSL may be applied to the common electrode CE.

The pixel electrode PXE and the common electrode CE may include a metal material with high reflectivity such as a stacked structure (Ti/Al/Ti) of aluminum (Al) and titanium (Ti), a stacked structure (ITO/Al/ITO) of aluminum and an indium tin oxide (ITO), an Ag—Pd—Cu (APC) alloy, and a stacked structure (ITO/APC/ITO) of an APC alloy and ITO. The APC alloy may be an alloy of silver (Ag), palladium (Pd), and copper (Cu).

FIG. 4 illustrates that the light emitting element LE may be a flip-chip type micro LED in which a first contact electrode CTE1 and a second contact electrode CTE2 may be disposed to face the pixel electrode PXE and the common electrode CE. The light emitting element LE may include an inorganic material such as a gallium nitride (GaN). A length in the first direction DR1, a length in the second direction DR2, and a length in the third direction DR3 of the light emitting element LE may be several to hundreds of micrometers (μm), respectively. For example, the length in the first direction DR1, the length in the second direction DR2, and the length in the third direction DR3 of the light emitting element LE may be about 100 μm or less, respectively.

The light emitting element LE may be grown on a semiconductor substrate such as a silicon wafer and be formed. The light emitting element LE may be transferred (e.g., directly transferred) from the silicon wafer onto the pixel electrode PXE and the common electrode CE of the substrate SUB. The light emitting element LE may be transferred onto the pixel electrode PXE and the common electrode CE of the substrate SUB through an electrostatic method using an electrostatic head or a stamp method using an elastic polymer material such as polydimethylsiloxane (PDMS) or silicon as a carrier substrate.

Referring to FIG. 4, each of the light emitting elements LE may be a light emitting structure including a base substrate SPUB, an n-type semiconductor NSEM, an active layer MQW, a p-type semiconductor PSEM, a first contact electrode CTE1, and a second contact electrode CTE2.

The base substrate SPUB may be, for example, a sapphire substrate, but embodiments of the disclosure may not be limited thereto.

The n-type semiconductor NSEM may be disposed on a surface of the base substrate SPUB. For example, the n-type semiconductor NSEM may be disposed on a lower surface of the base substrate SPUB (for example, an opposite direction of the third direction DR3). The n-type semiconductor NSEM may be made of, for example, a gallium nitride (GaN) doped with an n-type conductive dopant such as silicon (Si), germanium (Ge), selenium (Se), tellurium (Te), or tin (Sn).

The active layer MQW may be disposed on a portion of a surface of the n-type semiconductor NSEM. The active layer MQW may include a material having a single or multiple quantum well structure. In case that the active layer MQW includes a material having a multi-quantum well structure, multiple well layers and a barrier layer may be alternately stacked on each other. The well layer may be formed of InGaN, and the barrier layer may be formed of GaN or AlGaN, but may not be limited thereto. The active layer MQW may have a structure in which a semiconductor material having large band gap energy and a semiconductor material having small band gap energy may be alternately stacked on each other, or may include group 3 to group 5 semiconductor materials according to a wavelength band of light that emits light.

The p-type semiconductor PSEM may be disposed on a surface (for example, a surface disposed in the opposite direction of the third direction DR3) of the active layer MQW. The p-type semiconductor PSEM may be made of, for example, a gallium nitride (GaN) doped with a p-type conductive dopant such as magnesium (Mg), zinc (Zn), calcium (Ca), barium (Ba), or the like.

The first contact electrode CTE1 may be disposed on the p-type semiconductor PSEM (for example, the opposite direction of the third direction DR3), and the second contact electrode CTE2 may be disposed on another portion of a surface of the n-type semiconductor NSEM (for example, the opposite direction of the third direction DR3). Another portion of a surface of the n-type semiconductor NSEM on which the second contact electrode CTE2 may be disposed may be disposed to be spaced apart from a portion of a surface of the n-type semiconductor NSEM on which the active layer MQW may be disposed.

The first contact electrode CTE1 and the pixel electrode PXE may be bonded to each other through a conductive adhesive member (not shown) such as an anisotropic conductive film (ACF) or an anisotropic conductive paste (ACP). The first contact electrode CTE1 and the pixel electrode PXE may be bonded to each other through a soldering process.

A bank 190 covering an edge of the pixel electrode PXE and an edge of the common electrode CE may be disposed on the second insulating film 171. The bank 190 may be formed as an organic film including an acryl resin, an epoxy resin, a phenolic resin, a polyamide resin, a polyimide resin, and the like.

A bank insulating film 191 may be disposed on the bank 190. The bank insulating film 191 may cover the edge of the pixel electrode PXE and the edge of the common electrode CE. The bank insulating film 191 may be formed as an inorganic film, for example, a silicon nitride layer, a silicon oxynitride layer, a silicon oxide layer, a titanium oxide layer, or an aluminum oxide layer.

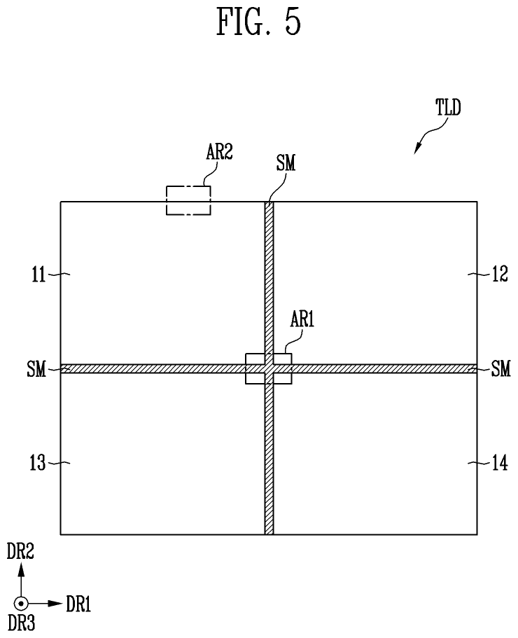

FIG. 5 illustrates a perspective view of a tiled display device TLD including multiple display devices according to an embodiment.

Referring to FIG. 5, the tiled display device TLD may include multiple display devices 11, 12, 13, and 14 and a seaming portion SM. For example, the tiled display device TLD may include a first display device 11, a second display device 12, a third display device 13, and a fourth display device 14.

Multiple display devices 11, 12, 13, and 14 may be arranged in a lattice form. The display devices 11, 12, 13, and 14 may be arranged in a matrix form of M (M may be an integer greater than or equal to 1) rows and N (N may be an integer greater than or equal to 1) columns. For example, the first display device 11 and the second display device 12 may be adjacent to each other in the first direction DR1. The first display device 11 and the third display device 13 may be adjacent to each other in the second direction DR2. The third display device 13 and the fourth display device 14 may be adjacent to each other in the first direction DR1. The second display device 12 and the fourth display device 14 may be adjacent to each other in second direction DR2.

However, the number and disposition of the display devices 11, 12, 13, and 14 in the tiled display device TLD may not be limited to those shown in FIG. 5. The number and disposition of the display devices 11, 12, 13, and 14 included in the tiled display device TLD be set differently depending on the size of the display devices 11, 12, 13, 14 and the size of the tiled display device TLD and the shape of the tiled display device TLD.

Referring to FIG. 5, the display devices 11, 12, 13, and 14 may be shown as having a same size, but the disclosure may not be limited thereto. For example, at least one of the display devices 11, 12, 13, and 14 may have a different size from the rest of the display devices.

Each of the display devices 11, 12, 13, and 14 may have a rectangular shape including a long side and a short side. The display devices 11, 12, 13, and 14 may be disposed while their long sides or short sides may be extended to each other. Some or all of the display devices 11, 12, 13, and 14 may be disposed at the edge of the tiled display device TLD, and may form a side of the tiled display device TLD. At least one of the display devices 11, 12, 13, and 14 may be disposed on at least a corner of the tiled display device TLD, and may form two adjacent sides of the tiled display device TLD. At least one of the display devices 11, 12, 13, and 14 may be surrounded by other display devices.

The display device 10 described with reference to FIGS. 1-4 and each of the display devices 11, 12, 13, and 14 of FIG. 5 may be substantially the same. Therefore, a description of each of the display devices 11, 12, 13, and 14 may be omitted.

The seaming portion SM may include a coupling member or an adhesive member. The display devices 11, 12, 13, and 14 may extend to each other through a bonding member or an adhesive member of the seaming portion SM. The seaming portion SM may be disposed between the first display device 11 and the second display device 12, between the first display device 11 and the third display device 13, between the second display device 12 and the fourth display device 14, and the third display device 13 and the fourth display device 14.

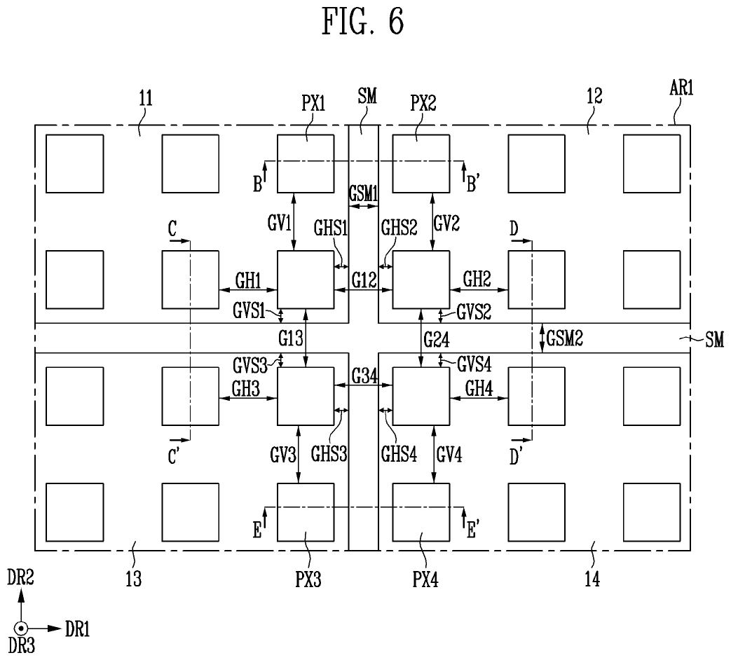

FIG. 6 illustrates an enlarged schematic diagram of an area AR1 of FIG. 5 in detail.

Referring to FIG. 6, the seaming portion SM may have a planar shape of a cross or plus sign in a central area of the tiled display device TLD in which the first display device 11, the second display device 12, the third display device 13, and the fourth display device 14 may be adjacent to each other.

The first display device 11 may include first pixels PX1 arranged in a matrix format in the first direction DR1 and the second direction DR2 so as to display an image. The second display device 12 may include second pixels PX2 arranged in a matrix format in the first direction DR1 and the second direction DR2 so as to display an image. The third display device 13 may include third pixels PX3 arranged in a matrix format in the first direction DR1 and the second direction DR2 so as to display an image. The fourth display device 14 may include fourth pixels PX4 arranged in a matrix format in the first direction DR1 and the second direction DR2 so as to display an image.

A minimum distance between adjacent first pixels PX1 in the first direction DR1 may be defined as a first horizontal separation distance GH1, and a minimum distance between adjacent second pixels PX2 in the first direction DR1 may be defined as a second horizontal separation distance GH2. The first horizontal separation distance GH1 and the second horizontal separation distance GH2 may be substantially equal.

The seaming portion SM may be disposed between the first pixel PX1 and the second pixel PX2 adjacent in the first direction DR1. A minimum distance G12 between the first pixel PX1 and the second pixel PX2 adjacent in the first direction DR1 may be a sum of a minimum distance GHS1 between the first pixel PX1 and the seaming portion SM in the first direction DR1, a minimum distance GHS2 between the second pixel PX2 and the seaming portion SM in the first direction DR1, and a width GSM1 of the seaming portion SM in the first direction DR1.

The minimum distance G12 between the first pixel PX1 and the second pixel PX2 adjacent in the first direction DR1, the first horizontal separation distance GH1, and the second horizontal separation distance GH2 may be substantially equal. For this, the minimum distance GHS1 between the first pixel PX1 and the seaming portion SM in the first direction DR1 may be smaller than the first horizontal distance GH1, and the minimum distance GHS2 between the second pixel PX2 and the seaming portion SM in the first direction DR1 may be smaller than the second horizontal distance GH2. The width GSM1 of the seaming portion SM in the first direction DR1 may be smaller than the first horizontal separation distance GH1 or the second horizontal separation distance GH2.

A minimum distance between adjacent third pixels PX1 in the first direction DR1 may be defined as a third horizontal separation distance GH3, and a minimum distance between adjacent fourth pixels PX4 in the first direction DR1 may be defined as a fourth horizontal separation distance GH4. The third horizontal separation distance GH3 and the fourth horizontal separation distance GH4 may be substantially equal.

The seaming portion SM may be disposed between the third pixel PX3 and the fourth pixel PX4 adjacent in the first direction DR1. A minimum distance G34 between the third pixel PX3 and the fourth pixel PX4 adjacent in the first direction DR1 may be a sum of a minimum distance GHS3 between the third pixel PX3 and the seaming portion SM in the first direction DR1, a minimum distance GHS4 between the fourth pixel PX4 and the seaming portion SM in the first direction DR1, and the width GSM1 of the seaming portion SM in the first direction DR1.

The minimum distance G34 between the third pixel PX3 and the fourth pixel PX4 adjacent in the first direction DR1, the third horizontal separation distance GH3, and the fourth horizontal separation distance GH4 may be substantially equal. To this end, the minimum distance GHS3 between the third pixel PX3 and the seaming portion SM in the first direction DR1 may be smaller than the third horizontal separation distance GH3, and the minimum distance GHS4 between the fourth pixel PX4 and the seaming portion SM in the first direction DR1 may be smaller than the fourth horizontal separation distance GH4. The width GSM1 of the seaming portion SM in the first direction DR1 may be smaller than the third horizontal separation distance GH3 or the fourth horizontal separation distance GH4.

A minimum distance between adjacent first pixels PX1 in the second direction DR2 may be defined as a first vertical separation distance GV1, and a minimum distance between adjacent third pixels PX3 in the second direction DR2 may be defined as a third vertical separation distance GV3. The first vertical separation distance GV1 and the third vertical separation distance GV3 may be substantially equal.

The seaming portion SM may be disposed between the first pixel PX1 and the third pixel PX3 adjacent in the second direction DR2. A minimum distance G13 between the first pixel PX1 and the third pixel PX3 adjacent in the second direction DR2 may be a sum of a minimum distance GVS1 between the first pixel PX1 and the seaming portion SM in the second direction DR2, a minimum distance GVS3 between the third pixel PX3 and the seaming portion SM in the second direction DR2, and a width GSM2 of the seaming portion SM in the second direction DR2.

The minimum distance G13 between the first pixel PX1 and the third pixel PX3 adjacent in the second direction DR2, the first vertical separation distance GV1, and the third vertical separation distance GV3 may be substantially equal. To this end, the minimum distance GVS1 between the first pixel PX1 and the seaming portion SM in the second direction DR2 may be smaller than the first vertical separation distance GV1, and the minimum distance GVS3 between the third pixel PX3 and the seaming portion SM in the second direction DR2 may be smaller than the third vertical separation distance GV3. The width GSM2 of the seaming portion SM in the second direction DR2 may be smaller than the first vertical separation distance GV1 or the third vertical separation distance GV3.

A minimum distance between adjacent second pixels PX2 in the second direction DR2 may be defined as a second vertical separation distance GV2, and a minimum distance between adjacent fourth pixels PX4 in the second direction DR2 may be defined as a fourth vertical separation distance GV4. The second vertical separation distance GV2 and the fourth vertical separation distance GV4 may be substantially equal.

The seaming portion SM may be disposed between the second pixel PX2 and the fourth pixel PX4 adjacent in the second direction DR2. A minimum distance G24 between the second pixel PX2 and the fourth pixel PX4 adjacent in the second direction DR2 may be a sum of a minimum distance GVS2 between the second pixel PX2 and the seaming portion SM in the second direction DR2, a minimum distance GVS4 between the fourth pixel PX4 and the seaming portion SM in the second direction DR2, and the width GSM2 of the seaming portion SM in the second direction DR2.

The minimum distance G24 between the second pixel PX2 and the fourth pixel PX4 adjacent in the second direction DR2, the second vertical separation distance GV2, and the fourth vertical separation distance GV4 may be substantially equal. To this end, the minimum distance GVS2 between the second pixel PX2 and the seaming portion SM in the second direction DR2 may be smaller than the second vertical separation distance GV2, and the minimum distance GVS4 between the fourth pixel PX4 and the seaming portion SM in the second direction DR2 may be smaller than the fourth vertical separation distance GV4. The width GSM2 of the seaming portion SM in the second direction DR2 may be smaller than the second vertical separation distance GV2 or the fourth vertical separation distance GV4.

As shown in FIG. 6, in order to prevent the seaming SM between images displayed by the display devices 11, 12, 13, and 14 from being viewed, the minimum distance between the pixels of adjacent display devices and the minimum distance between the pixels in each of the display devices may be substantially equal.

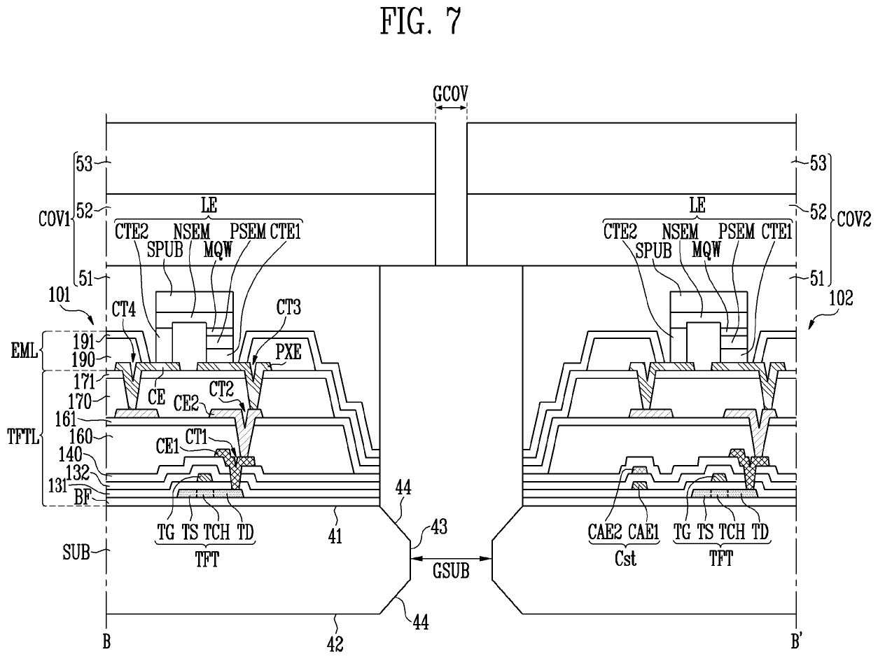

FIG. 7 illustrates a schematic cross-sectional view of an example of a tiled display device taken along line B-B′ of FIG. 6.

Referring to FIG. 7, the first display device 11 (see FIG. 6) includes a first display panel 101 and a first front cover COV1. The second display device 12 (see FIG. 6) includes a second display panel 102 and a second front cover COV2.

Each of the first display panel 101 and the second display panel 102 includes the substrate SUB, the thin film transistor layer TFTL, and the light emitting element layer EML.

The thin film transistor layer TFTL and the light emitting element layer EML have already been described in detail with reference to FIG. 4. In FIG. 7, descriptions that may be described in FIG. 4 will be omitted.

The substrate SUB may include a first surface 41 on which the thin film transistor layer TFTL may be disposed, a second surface 42 facing the first surface, and a first side surface 43 disposed between the first surface 41 and the second surface 42. The first surface 41 may be a front or upper surface of the substrate SUB, and the second surface 42 may be a back or lower surface of the substrate SUB.

The substrate SUB may further include a chamfer surface 44 that may be disposed between the first surface 41 and the first side surface 43 and between the second surface 42 and the first side surface 43. The thin film transistor layer TFTL and the light emitting element layer EML may not be disposed on the chamfer surface 44. Due to the chamfer surface 44, the substrate SUB of the first display device 11 and the substrate of the second display device 12 may be prevented from colliding and being damaged.

The chamfer surface 44 may be disposed between another side surfaces except the first surface 41 and the first side surface 43, and between another side surfaces except the second surface 42 and the first side surface 43, respectively. For example, in case that the first display device 11 and the second display device 12 have a rectangular planar shape as shown in FIG. 5, the substrate SUB may be disposed between the first surface 41 and the second, third, and fourth side surfaces, respectively, and between the second surface 42 and the second, third, and fourth side surfaces, respectively.

The first front cover COV1 may be disposed on the chamfer surface 44 of the substrate SUB. For example, the first front cover COV1 may be further protrude than the substrate SUB in the first direction DR1 and the second direction DR2. Accordingly, a distance GSUB between the substrate SUB of the first display device 11 and the substrate SUB of the second display device 12 may be greater than a distance GCOV between the first front cover COV1 and the second front cover COV2.

Each of the first front cover COV1 and the second front cover COV2 may include an adhesive member 51, a light transmittance control layer 52 disposed on the adhesive member 51, and an anti-glare layer 53 disposed on the light transmittance control layer 52.

Hereinafter, the first front cover COV1 may be taken as an example to describe its components, but the description of the corresponding components may also be applied to the description of the second front cover COV2 as it is.

The adhesive member 51 may be configured to attach the first front cover COV1 to the light emitting element layer EML of the first display panel 101. The adhesive member 51 may be a transparent adhesive member capable of transmitting light. For example, the adhesive member 51 may be an optical clear adhesive film (also referred to as an OCA film) or an optically clear resin (OCR).

The light transmittance control layer 52 may be configured to lower the transmittance of external light incident from the outside or to lower the transmittance of reflected light that may be re-incident after external light transmitted through the light transmittance control layer 52 may be reflected by the first display panel 101 and the second display panel 102. As the first front cover COV1 includes the light transmittance control layer 52, it may be possible to prevent the seaming portion SM (see FIG. 6) from being visually recognized from the outside. Accordingly, a seamless type tiled display device TLD (see FIG. 5) may be implemented.

The anti-glare layer 53 may be configured to alleviate a phenomenon in which light reflected by a metal wire or the like inside the display device 10 (see FIG. 1) may be visually recognized from the outside. More specifically, the display device 10 may include a metal wire of the thin film transistor layer TFTL or a metal electrode (for example, the pixel electrode PXE) on the thin film transistor layer TFTL, and external light incident from the outside may be reflected by the metal wire or the like, so that the reflected light may be visually recognized from the outside. Since excessive reflected light may be a factor that causes deterioration in visibility of an image, the anti-glare layer 53 may be designed to diffusely reflect external light and/or reflected light in order to prevent deterioration in the visibility of an image. As the first front cover COV1 includes the anti-glare layer 53, a contrast ratio of an image displayed by the display device 10 (see FIG. 1) may be increased.

The light transmittance control layer 52 may be implemented as, for example, a phase retardation layer. The anti-glare layer 53 may be implemented as, for example, a polarizing plate. However, the embodiments of the disclosure may not be limited thereto.

The example of the tiled display device taken along lines C-C′, D-D′, and E-E′ of FIG. 6 and the example of the tiled display device taken along B-B′ described in with reference to FIG. 7 may be substantially the same.

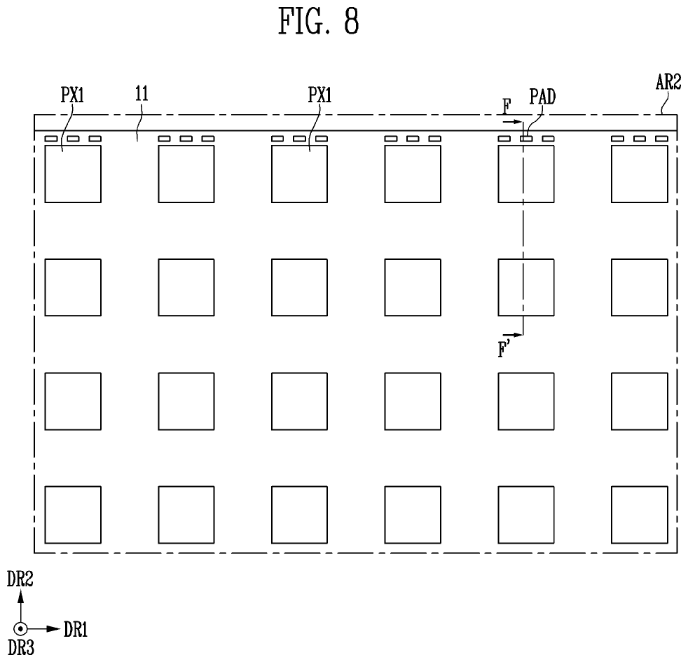

FIG. 8 illustrates an enlarged layout schematic of an area AR2 of FIG. 5 in detail.

FIG. 8 illustrates pads PAD and first pixels PX1 disposed on an upper side of the first display device 11.

Referring to FIG. 8, at least one pad PAD may be disposed on an upper edge of the first display device 11. In case that data lines (not shown) of the first display device 11 extend in the second direction DR2, the pad PAD may be disposed on the upper edge and/or lower edge of the first display device 11. In case that the data lines of the first display device 11 extend in the first direction DR1, the pad PAD may be disposed on the left edge and the right edge of the first display device 11.

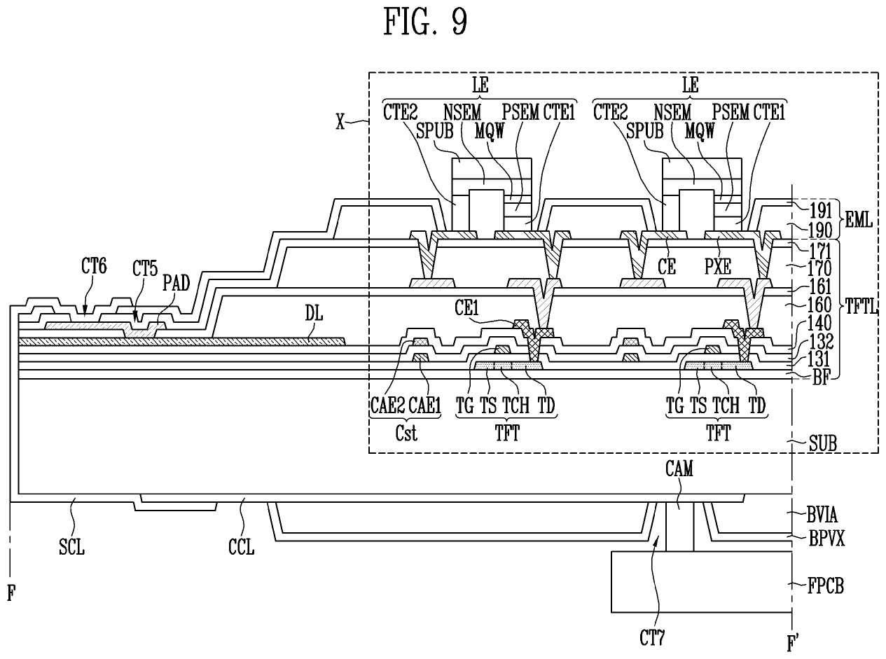

The pad PAD may be electrically connected to the data line. The pad PAD may be electrically connected to a side wire SCL (See FIG. 9).

The side wire SCL may be disposed on a side surface of the substrate SUB (see FIG. 9), and the side wire SCL may be disposed extending from the side surface to the lower surface (or the back surface). The side wire SCL may be electrically connected to a connection wire CCL (see FIG. 9) on the lower surface of the substrate SUB. A detailed description of the side wire SCL and the connection wire CCL will be described in more detail with reference to FIG. 9 below.

FIG. 9 illustrates a schematic cross-sectional view of an example of the tiled display device TLD (see FIG. 5) taken along F-F′ of FIG. 8.

In FIG. 9, same reference numerals may be denoted to same components as those shown in the schematic cross-sectional view of FIG. 4. A description that may be redundant to the description of FIG. 4 will be omitted.

Referring to FIG. 9, the pad PAD may be disposed on the first insulating film 161. The pad PAD may be exposed without being covered by the bank insulating film 191. The pad PAD and the pixel electrode PXE or the common electrode CE may include a same material. For example, the pad PAD may include a stacked structure (Ti/Al/Ti) of aluminum (AI) and titanium (TI), a stacked structure (ITO/Al/ITO) of aluminum (AI) and an ITO, an APC alloy, and a stacked structure (ITO/APC/ITO) of an APC alloy and an ITO. The pad PAD may include a metallic material having high reflectivity.

The first data metal layer DTL1 may include a data line DL. The data line DL may be disposed on the interlayer insulating film 140. For example, the data line DL and the first connection electrode CE1 may be disposed on a same layer and may include a same material.

The pad PAD may be electrically connected to the data line DL through the fifth contact hole CT5 penetrating the first insulating film 161. In some cases, a link wire (not shown) may be further disposed between the pad PAD and the data line DL. The pad PAD and the data line DL may not be connected (e.g., not be directly connected) but electrically connected through the link wire.

The connection wire CCL may be disposed on the back surface of the substrate SUB. The connecting wire CCL may be a single layer or a multilayer that may be made of one of molybdenum (Mo), aluminum (Al), chromium (Cr), gold (Au), titanium (Ti), nickel (Ni), neodymium (Nd), and copper (Cu) or an alloy thereof.

A back planarization film BVIA may be disposed to cover a portion of the connection wire CCL. The back planarization film BVIA may be formed as an organic film including an acryl resin, an epoxy resin, a phenolic resin, a polyamide resin, a polyimide resin, and the like.

A back insulating film BPVX may be disposed on the lower surface of the back planarization film BVIA (for example, while covering the back planarization film BVIA). The back insulating film BPVX may include an inorganic film. For example, the inorganic film may be formed as a silicon nitride layer, a silicon oxynitride layer, a silicon oxide layer, a titanium oxide layer, or an aluminum oxide layer.

The side wire SCL may be disposed to extend from the lower edge of the substrate SUB to the side and upper edges of the substrate SUB.

An end of the side wire SCL may be electrically connected to the connection wire CCL. For example, the end of the side wire SCL may be electrically connected to the side and lower surfaces of the connection wire CCL. Another end of the side wire SCL may be electrically connected to the pad PAD. For example, another end of the side wire SCL may be electrically connected to the pad PAD through the sixth contact hole CT6 penetrating the bank insulating film 191.

The side wire SCL may be disposed on the side surface of the substrate SUB, the side surface of the buffer film BF, the side surface of the first gate insulating film 131, the side surface of the second gate insulating film 132, the side surface of the interlayer insulating film 140, the side surface of the first insulating film 161, and the side surface of the second insulating film 171.

A flexible film FPCB may be disposed under the back insulating film BPVX (for example, in the direction of the lower surface of the substrate SUB). The flexible film FPCB can be electrically connected to the connection wire CCL by using a conductive adhesive member CAM.

The flexible film FPCB may be extended to the connection wire CCL through the seventh contact hole CT7.

The seventh contact hole CT7 may be a hole penetrating the back planarization film BVIA and the back insulating film BPVX, or may be a hole formed in an area in which the back planarization film BVIA and the back insulating film BPVX may be previously removed.

A data driving circuit (not shown) for supplying data voltages to the data lines DL may be mounted on a surface of the flexible film FPCB. The flexible film FPCB, for example, may be implemented as a flexible printed circuit board, but may not be limited thereto. The data driving circuit may be implemented as, for example, a source driver integrated circuit (SDIC).

The conductive adhesive member CAM that electrically connects the flexible film FPCB and the connection wire CCL may be, for example, an anisotropic conductive film (ACF) or an anisotropic conductive paste (ACP), but may not be limited thereto.

Referring to FIG. 9, the flexible film FPCB may be disposed on the back surface of the substrate SUB, and may be extended to the pad PAD through the connection wire CCL and the side wire SCL. Accordingly, the pixel PX may be disposed up to the edge area of the display panel 100 (see FIG. 1), and a ratio of the display area in which an image is displayed may be increased.

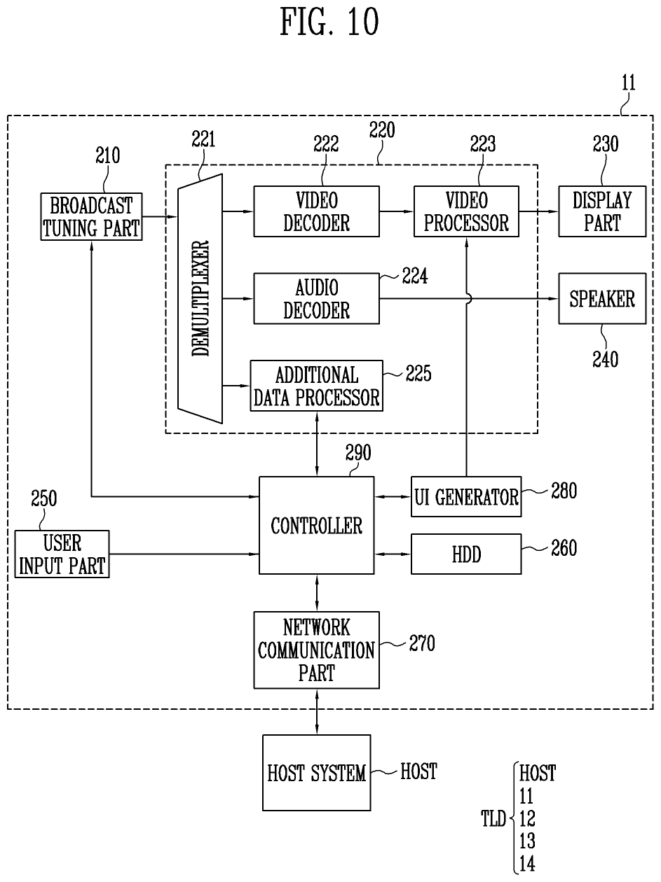

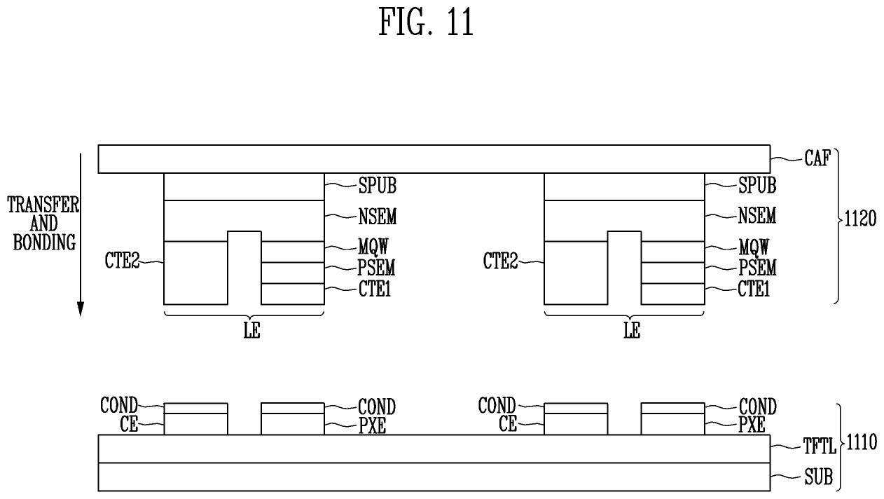

FIG. 10 illustrates a schematic block diagram of a tiled display device TLD according to an embodiment.

Referring to FIG. 10, the tiled display device TLD according to the embodiment may include a host system HOST and multiple display devices 11, 12, 13, and 14.

FIG. 10 illustrates that the host system HOST controls the first display device 11 for better understanding and ease of description, but the host system HOST may also perform a function of controlling the display devices 11, 12, 13, and 14.

The host system HOST may be implemented as, for example, a set-top box, an application processor (AP), and the like.

A user's command may be inputted to the host system HOST in various formats. For example, a command by a user's touch input may be inputted to the host system HOST. A user's command may be inputted to the host system HOST through an external input device (for example, keyboard input or remote controller button input).

The host system HOST may receive an original video data corresponding to an original image from the outside. The host system HOST may divide original video data by the number of the display devices 11, 12, 13, and 14. For example, the host system HOST may divide the original video data into a first video data corresponding to a first image, a second video data corresponding to a second image, a third video data corresponding to a third image, and a fourth video data corresponding to a fourth image, corresponding to the first display device 11, the second display device 12, the third display device 13, and the fourth display device 14. The host system HOST may transmit the first video data to the first display device 11, transmit the second video data to the second display device 12, transmit the third video data to the third display device 13, and transmit the fourth video data to the fourth display device 14.

The first display device 11 may display the first image according to the first video data, the second display device 12 may display the second image according to the second video data, the third display device 13 may display the third image according to the third video data, and the fourth display device 14 may display the fourth image according to the fourth video data. Accordingly, the user may view the original image in which the first to fourth images displayed on the display devices 11, 12, 13, and 14 may be combined.

Referring to FIG. 10, the first display device 11 may include a broadcast tuning part 210, a signal processor 220, a display part 230, a speaker 240, a user input part 250, a hard disk drive (HDD) 260, a network communication part 270, a user interface (UI) generator 280, and a controller 290.

The broadcast tuning part 210 may receive a broadcast signal of a corresponding channel through an antenna by tuning a channel frequency (e.g., predetermined or selectable channel frequency) according to control of the controller 290. The broadcast tuning part 210 may include a channel detection module and a radio frequency (RF) demodulation module.

The broadcast signal demodulated by the broadcast tuning part 210 may be processed by the signal processor 220 to be outputted to the display part 230 and the speaker 240. Here, the signal processor 220 may include a demultiplexer 221, a video decoder 222, a video processor 223, an audio decoder 224, and an additional data processor 225.

The demultiplexer 221 separates the demodulated broadcast signal into a video signal, an audio signal, and additional data. The separated video signal, audio signal, and additional data may be restored by the video decoder 222, the audio decoder 224, and the additional data processor 225, respectively. The video decoder 222, the audio decoder 224, and the additional data processor 225 may restore a broadcast signal into a decoding format corresponding to an encoding format upon transmission.

The decoded video signal may be converted by the video processor 223 to match a vertical frequency, a resolution, a screen ratio, and the like that meet an output standard of the display part 230, and the decoded audio signal may be outputted to the speaker 240.

The display part 230 includes the display panel 100 (see FIG. 1) on which an image may be displayed and a panel driver that controls driving of the display panel 100.

The user input part 250 may receive a signal transmitted by the host system HOST. The user input part 250 allows the user to receive commands related to communication with other display devices as well as data related to channel selection, user interface (UI) menu selection, and operation transmitted by the host system HOST. Data for selection and input may be provided to be inputted.

The HDD 260 stores various software programs including operating system (OS) programs, recorded broadcast programs, moving pictures, photos, and other data, and may be realized as a storage medium such as a hard disk or a non-volatile memory. The HDD 260 may be referred to as a storage portion.

The network communication part 270 may be for short-distance communication with the host system HOST and other display devices, and may be a communication module including an antenna pattern that can implement mobile communication, data communication, Bluetooth, RF, Ethernet, and the like may be implemented. The network communication part 270 may be a technical standard or communication method for mobile communication (for example, Global System for Mobile communication (GSM), Code Division Multi Access (CDMA), Code Division Multi Access (CDMA2000)) through an antenna pattern to be described later. 2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), 5G, and the like) may transmit/receive a radio signal with at least one of a base station, an external terminal, and a server on a mobile communication network.

The network communication part 270 may transmit/receive a wireless signal in a communication network according to wireless Internet technologies through an antenna pattern to be described later. As wireless Internet technologies, for example, WLAN (Wireless LAN), Wi-Fi (Wireless-Fidelity), Wi-Fi Direct, DLNA (Digital Living Network Alliance), WiBro (Wireless Broadband), WiMAX (World Interoperability for Microwave Access), High Speed Downlink Packet Access (HSDPA), High Speed Uplink Packet Access (HSUPA), Long Term Evolution (LTE), Long Term Evolution-Advanced (LTE-A), and the like, and the antenna pattern transmits and receives data according to at least one wireless Internet technology within a range including Internet technologies not listed above.

The UI generator 280 generates a UI menu for communication with the host system HOST and other display devices, and may be implemented by an algorithm code and an on screen display (OSD) IC (integrated circuit). The UI menu for communication with the host system HOST and other display devices may be a menu for designating a counterpart digital TV for communication and selecting a desired function.

The controller 290 may be in charge of overall control of the first display device 11 and may be in charge of communication control of the host system HOST and other display devices 12, 13, and 14, and a corresponding algorithm code for control may be stored and, and it may be implemented by a micro controller part (MCU) in which the stored algorithm code may be executed.

The controller 290 controls to transmit the corresponding control command and data to the host system HOST and other display devices 12, 13, and 14 through the network communication part 270 according to the input and selection of the user input part 250. Of course, in case that a control command (e.g., predetermined or selectable control command) and data may be input from the host system HOST and other display devices 12, 13, and 14, an operation may be performed according to the control command.

A schematic block diagram of the second display device 12, a schematic block diagram of the third display device 13, and a schematic block diagram of the fourth display device 14 and the schematic block diagram of the first display device 11 described with reference to FIG. 10 may be substantially a same, so duplicate descriptions will be omitted.

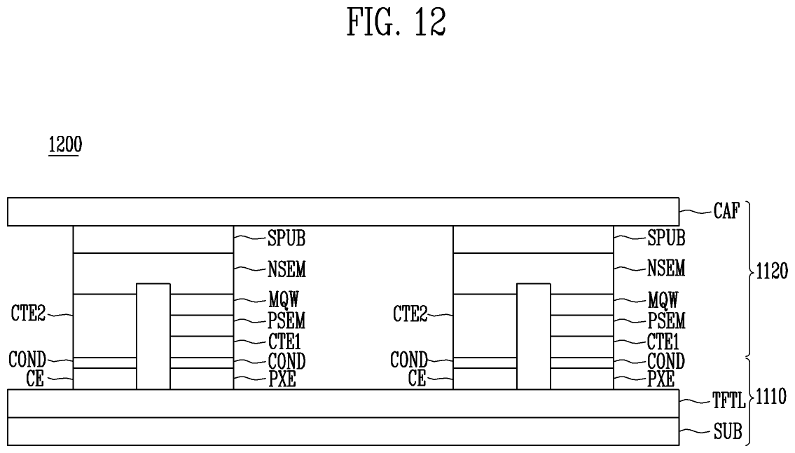

FIG. 11 schematically illustrates a transfer process of a light emitting element LE. FIG. 12 illustrates an example of a backplane substrate 1200 to which the light emitting element LE may be transferred.

Referring to FIG. 11, a thin film transistor substrate 1110 and a transfer substrate 1120 transferred to the thin film transistor substrate 1110 may be shown.

The thin film transistor substrate 1110 may be simply illustrated as including the substrate SUB, the thin film transistor layer TFTL formed on the substrate, and the common electrode CE and the pixel electrode PXE formed on the thin film transistor layer TFTL.

The transfer substrate 1120 may include multiple light emitting elements LE and a carrier substrate CAF configured to transfer and implant the light emitting elements LE on the thin film transistor substrate 1110. A process of transferring and implanting the light emitting element LE to the thin film transistor substrate 1110 may be also referred to as a transfer process.

In order to transfer more light emitting elements LE onto the thin film transistor substrate 1110 in a transfer process, the transfer substrate 1120 may further include a carrier substrate CAF to which multiple light emitting elements LE may be attached and detached. For example, the carrier substrate CAF may be implemented as a carrier film including a polymer material having elasticity such as silicon described above, but embodiments of the disclosure may not be limited thereto.

The carrier substrate CAF may be attached to the base substrate SPUB of the light emitting element LE. The carrier substrate CAF may be detached and removed from the base substrate SPUB at some point after the transfer process is complete.

The light emitting element LE may be an inorganic light emitting element, and the light emitting element LE may be a micro light emitting diode (micro LED). Multiple light emitting elements LE may be transferred through the carrier substrate CAF in a transfer process.

For electrical connection between the light emitting element LE and the common electrode CE and the pixel electrode PXE, a bonding process may be performed after the transfer process. Through the bonding process, electrical resistance between the light emitting element LE and the common electrode CE may be reduced or electrical resistance between the light emitting element LE and the pixel electrode PXE may be reduced.

Referring to FIG. 11, the thin film transistor substrate 1110 may further include a conductive material COND disposed on the pixel electrode PXE and the common electrode CE.

The conductive material COND may be a component for increasing adhesion between each of the pixel electrode PXE and the common electrode CE and the light emitting element LE. The conductive material COND may be a component for reducing electrical resistance between each of the pixel electrode PXE and the common electrode CE and the light emitting element LE.

The conductive material COND may be, for example, an anisotropic conductive film (ACF) or an anisotropic conductive paste (ACP). The conductive material COND may include, for example, a metallic conductive ball having conductivity (not shown). The conductive material COND may become conductive by receiving pressure and heat. However, the embodiment of the conductive material COND may not be limited thereto.

Referring to FIG. 11, although the conductive material COND may be shown to be disposed on both the pixel electrode PXE and the common electrode CE, the conductive material COND may be disposed only on the pixel electrode PXE or only on the common electrode CE. In some cases, the conductive material COND disposed on the pixel electrode PXE and the common electrode CE may have different thicknesses.

Multiple light emitting elements LE may be transferred to the thin film transistor substrate 1110 through the transfer process and the bonding process as described above. Referring to FIG. 12, the backplane substrate 1200 may include the thin film transistor substrate 1110 and the transfer substrate 1120.

The backplane substrate 1200 shown in FIG. 12 may be in a state in which the light emitting elements LE (see FIG. 11) attached to the carrier substrate CAF are transferred onto the thin film transistor substrate 1110.

The backplane substrate 1200 may further include a parent substrate (not shown). After both the transfer process and the bonding process may be performed, the parent substrate may be separated from the substrate SUB (for example, the lower surface of the substrate SUB) and removed. The parent substrate, for example, may be a curable substrate including glass or the like, or may be a flexible substrate including plastic.

The backplane substrate 1200, for example, may include a substrate SUB for forming a display device 10 (see FIG. 1).

The backplane substrate 1200 may include, for example, a substrate SUB on which two or more display devices 10 (see FIG. 1) may be simultaneously formed. After the transfer process and the bonding process for the backplane substrate 1200 are completed, a scribing process for cutting the substrate SUB may be performed. Through the scribing process, two or more display devices 10 may be respectively divided. A scribing line at which the substrate SUB may be cut may be physically marked on the substrate SUB, but may not be limited thereto. The light emitting element LE (see FIG. 11) may not be transferred to the scribing line at which the substrate SUB is cut. The light emitting element LE may not be bonded to the scribing line.

The backplane substrate 1200 may include, for example, the substrate SUB for forming the display devices 11, 12, 13, and 14 (see FIG. 5) configuring the tiled display device TLD (see FIG. 5). An area in which the pads PAD (see FIG. 9) may be disposed on the substrate SUB or an area in which the side wire SCL (see FIG. 9) may be disposed on the substrate SUB may be an area in which the light emitting element LE may not be transferred and an area onto which the light emitting element LE may not be bonded.

In embodiments of the disclosure, the transfer and bonding processes as shown in FIG. 11 may be performed by coupling (or adsorbing) the carrier substrate CAF to which the light emitting element LE is attached to a cylinder head and by disposing the carrier substrate CAF onto which the light emitting element LE is attached onto the thin film transistor substrate 1110.

Hereinafter, with reference to the drawings, a cylinder head and a method for driving a transfer and bonding system using the same according to embodiments of the disclosure will be described in detail.

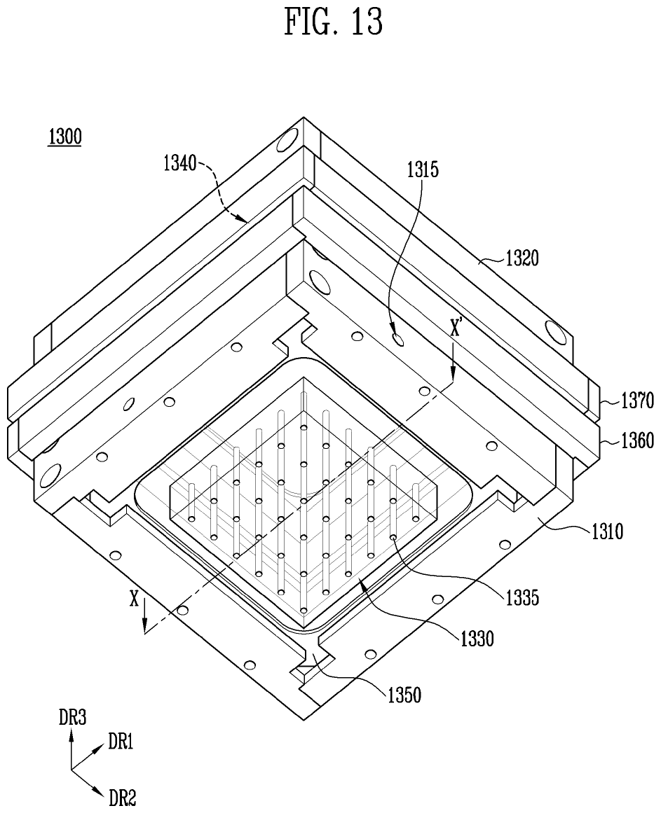

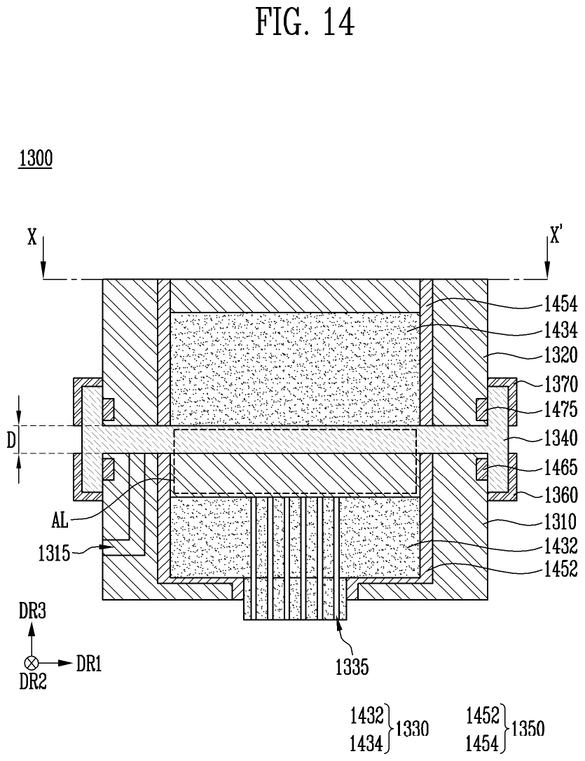

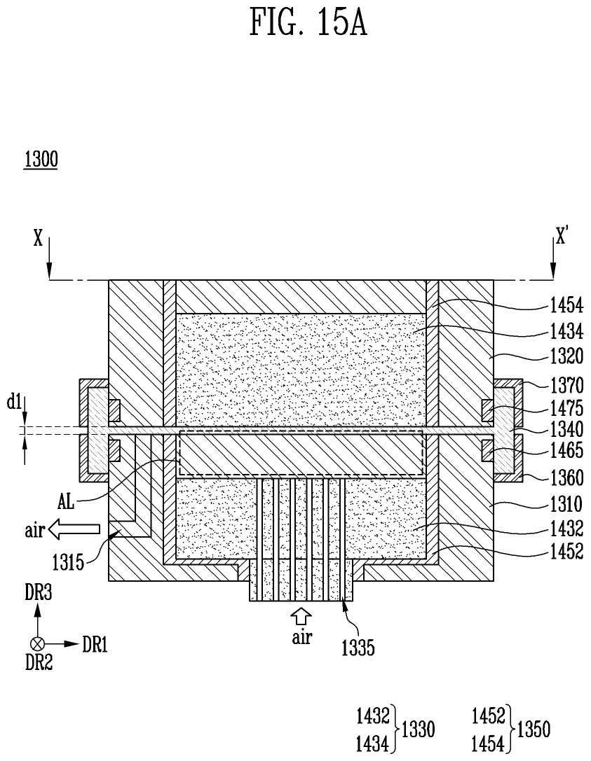

FIG. 13 illustrates a perspective view of a cylinder head 1300 according to embodiments of the disclosure. FIG. 14 illustrates a schematic cross-sectional view of the cylinder head of FIG. 13 taken along line X-X′.

Referring to FIG. 13 and FIG. 14, the cylinder head 1300 according to embodiments of the disclosure may include a first bracket 1310, a second bracket 1320, a transmissive member 1330, an elastic member 1340, a buffer member 1350, a first fastening portion 1360, a second fastening portion 1370, and the like.

The transmissive member 1330 may include a first transmissive member 1432 and a second transmissive member 1434. The buffer member 1350 may include a first buffer member 1452 and a second buffer member 1454.

The first bracket 1310 and the second bracket 1320 may be configured to accommodate the transmissive member 1330. The first bracket 1310 and the second bracket 1320 may be configured to be separated from each other. For example, the second bracket 1320 may be disposed in the third direction DR3 from the first bracket 1310.

In some embodiments, the first bracket 1310 may be integrally formed. In some embodiments, the first bracket 1310 may be configured to surround the transmissive member 1330 by including multiple parts that are assembled. For example, referring to FIG. 13, the first bracket 1310 may be shown as being a quadrangular shape having four sides as a whole. The first bracket 1310 may be divided into four parts corresponding to respective sides of the quadrangular shape, and respective parts may be assembled or fastened to configure a first bracket 1310.

In some embodiments, the second bracket 1320 may be integrally formed. In some embodiments, the second bracket 1320 may be configured to surround the transmissive member 1330 by including multiple parts that are assembled. For example, referring to FIG. 13, the second bracket 1320, like the first bracket 1310, may be shown as being a quadrangular shape having four sides as a whole. The second bracket 1320 may be divided into four parts corresponding to respective sides of the quadrangular shape, and respective parts may be assembled or fastened to configure a second bracket 1320.

The transmissive member 1330 may be accommodated in the first bracket 1310 and the second bracket 1320. For example, the transmissive member 1330 may be divided into a first transmissive member 1432 accommodated in the first bracket 1310 and a second transmissive member 1434 accommodated in the second bracket 1320. In some embodiments, the transmissive member 1330 may include a rigid material. In the above embodiment, the transmissive member 1330 may include quartz, glass, or the like. In some embodiments, the transmissive member 1330 may include a flexible material. In the above embodiment, the transmissive member 1330 may include a flexible light transmissive plastic or the like.

The transmissive member 1330 may include at least one first air path 1335. At least one of the first bracket 1310 and the second bracket 1320 may include a second air path 1315. Referring to FIG. 13, an embodiment in which the first bracket 1310 includes the second air path 1315 is illustrated as an example. Hereinafter, for better understanding and ease of description, the embodiment in which the first bracket 1310 includes the second air path 1315 will be described as an example. However, the embodiments of the disclosure may not be limited thereto.

In some embodiments, the at least one first air path may include multiple first air paths 1335. For example, the first air paths 1335 may be arranged in a lattice form.

The at least one first air path 1335 may be configured to allow air to enter and exit. For example, air may be introduced from the outside of the cylinder head 1300 through the at least one first air path 1335, or air may be discharged to the outside of the cylinder head 1300 through the at least one first air path 1335.

The second air path 1315 may be configured to allow air to enter and exit. For example, air may be introduced from the outside of the cylinder head 1300 through the second air path 1315, or air may be discharged to the outside of the cylinder head 1300 through the second air path 1315.

The at least one first air path 1335 and the second air path 1315 may extend to each other. In the above embodiment, air introduced from the outside of the cylinder head 1300 through the at least one first air path 1335 may be discharged to the outside of the cylinder head 1300 through the second air path 1315. Air introduced into the cylinder head 1300 through the second air path 1315 may be discharged to the outside of the cylinder head 1300 through the at least one first air path 1335.

The first bracket 1310 and the second bracket 1320 may be spaced apart from each other (for example, spaced apart from each other by a distance (e.g., predetermined or selectable distance) D). An air layer AL may be formed in a space inside the cylinder head 1300 formed by separating the first bracket 1310 and the second bracket 1320. Air introduced through the first air path 1335 and/or the second air path 1315 may be stored in the above inside space. A volume of the air layer AL may vary.

In some embodiments, the second air path 1315 may extend to an air pump (not shown) outside the cylinder head 1300. The air pump may be, for example, a blower configured to inject air into the second air path 1315. The air pump may be, for example, a vacuum pump configured to suck air from the second air path 1315.

The elastic member 1340 may be configured to connect the first bracket 1310 and the second bracket 1320. For example, the elastic member 1340 may be disposed on side surfaces of the first bracket 1310 and the second bracket 1320. In some embodiments, the elastic member 1340 may be further disposed on upper and/or back surfaces of the first bracket 1310 and the second bracket 1320. Hereinafter, for better understanding and ease of description, an embodiment in which the elastic member 1340 may be disposed on the side surfaces of the first bracket 1310 and the second bracket 1320 will be described as an example. However, the embodiments of the disclosure may not be limited thereto. The elastic member 1340 may surround the side surface of the first bracket 1310. The elastic member 1340 may surround the side surface of the second bracket 1320. Air may be stored in an inside space between the first bracket 1310 and the second bracket 1320 by the elastic member 1340, the first bracket 1310, and the second bracket 1320.

The elastic member 1340 may have elasticity. For example, in case that force may be applied to the elastic member 1340 in the third direction DR3, the elastic member 1340 may be stretchable. For example, in case that the force applied to the elastic member 1340 in the third direction DR3 is removed, the elastic member 1340 may be restored. The elastic member 1340 may be freely selected from an elastic material. For example, the elastic member 1340 may be realized with rubber or flexible plastic, but the embodiments of the disclosure may not be limited thereto.

By including the elastic member 1340, each movement of the first bracket 1310 and the second bracket 1320 may be freely controlled while they extend from each other.

The buffer member 1350 may be configured to protect the transmissive member 1330 from an external force. The first buffer member 1452 may be disposed between the transmissive member 1330 and the first bracket 1310. The second buffer member 1454 may be disposed between the transmissive member 1330 and the second bracket 1320. The buffer member 1350 may surround the transmissive member 1330. For example, the buffer member 1350 may absorb external forces applied from the first bracket 1310 and the second bracket 1320 while surrounding the side surface of the transmissive member 1330.

The first fastening portion 1360 may be configured to fix the elastic member 1340 to the first bracket 1310. The second fastening portion 1370 may be configured to fix the elastic member 1340 to the second bracket 1320. For example, the first fastening portion 1360 may include a fixing member 1465 (for example, a bolt or nut) for fixing the elastic member 1340 to the first bracket 1310. In some embodiments, the first fastening portion 1360 may further include a sealing member (not shown) (for example, an O-ring or the like) for sealing. For example, the second fastening portion 1370 may include a fixing member 1475 (for example, a bolt or nut) for fixing the elastic member 1340 to the second bracket 1320. In some embodiments, the second fastening portion 1370 may further include a sealing member (not shown) (for example, an O-ring or the like) for sealing.

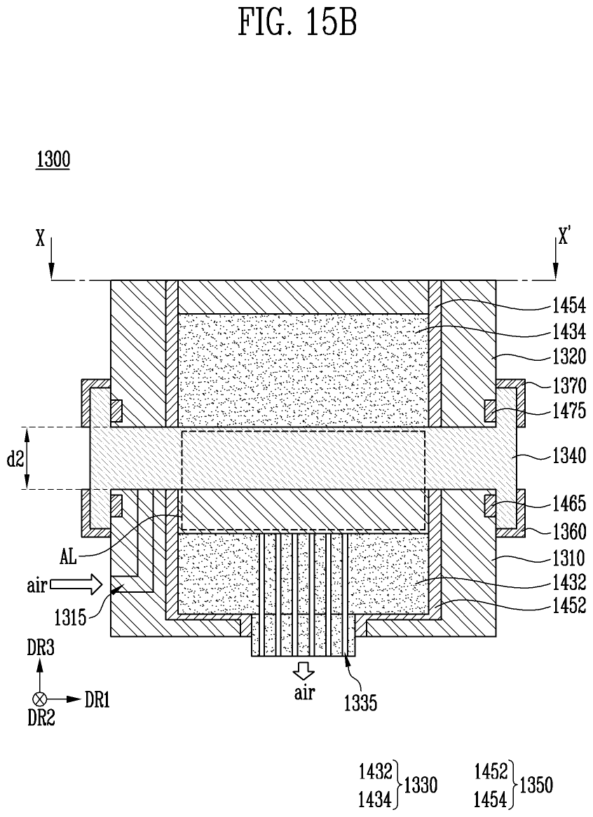

FIG. 15A illustrates a state in which air may be discharged from the cylinder head 1300 of FIG. 13 as an example. FIG. 15B illustrates a state in which air may be injected into the cylinder head 1300 of FIG. 13 as an example.

Referring to FIG. 15A, air may be discharged from the inside of the cylinder head 1300 (for example, from the air layer AL) through the second air path 1315. Accordingly, a distance d1 between the first bracket 1310 and the second bracket 1320 may be smaller than the distance D shown in FIG. 14. Air may be introduced from the outside of the cylinder head 1300 through the at least one first air path 1335, and thus the air pressure inside the cylinder head 1300 may be smaller than the air pressure outside the cylinder head 1300. The cylinder head 1300 may have an adsorption (or coupling) force.

Referring to FIG. 15B, air may be injected into the cylinder head 1300 (for example, the air layer AL) through the second air path 1315. The elastic member 1340 may be stretched. A distance d2 between the first bracket 1310 and the second bracket 1320 may be greater than the distance D shown in FIG. 14. The air layer AL may provide pressure to the first transmissive member 1432. According to Pascal's law, the pressure applied to the first transmissive member 1432 by the air layer AL may be uniform. Accordingly, the first transmissive member 1432 may uniformly provide pressure in a direction (for example, in the third direction DR3).

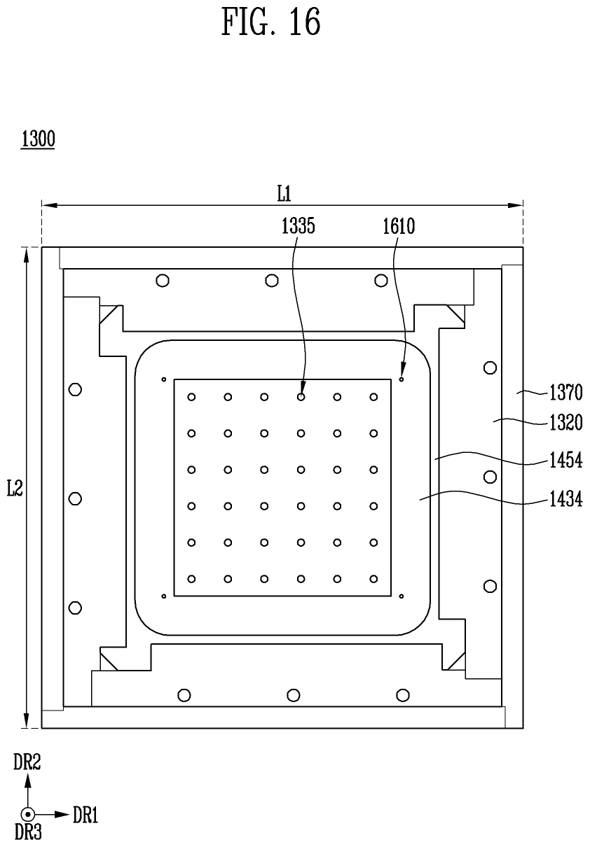

FIG. 16 illustrates a top view of the cylinder head 1300 of FIG. 13.

Referring to FIG. 16, in case that the cylinder head 1300 is viewed from the top, the second fastening portion 1370 may be disposed at the outermost side. For example, a width of the second fastening portion 1370 in a direction (for example, the first direction DR1) may be a first length L1. For example, a width of the second fastening portion 1370 in another direction (for example, the second direction DR2) may be a second length L2. In some embodiments, the first length L1 and the second length L2 may be a same, but the embodiments of the disclosure may not be limited thereto.

The second bracket 1320 may be disposed inside the second fastening portion 1370. In some embodiments, the aforementioned elastic member 1340 (see FIG. 14) may be further visible between the second fastening portion 1370 and the second bracket 1320.

The second transmissive member 1434 may be disposed inside the second bracket 1320. The second buffer member 1454 may be disposed between the second bracket 1320 and the second transmissive member 1434.

In case that the cylinder head 1300 according to the embodiments of the disclosure is viewed from the top, an alignment mark 1610 and the first air paths 1335 may be visible due to the optically transparent properties of transmissive member 1330. The alignment mark 1610 may be disposed at the aforementioned first bracket 1310 (see FIG. 13). The alignment mark 1610 according to the embodiments of the disclosure may be disposed on the first bracket 1310 in an area overlapping the transmissive member 1330 (see FIG. 13). The alignment mark 1610 may be configured to adjust the position of the cylinder head 1300 according to the embodiments of the disclosure.

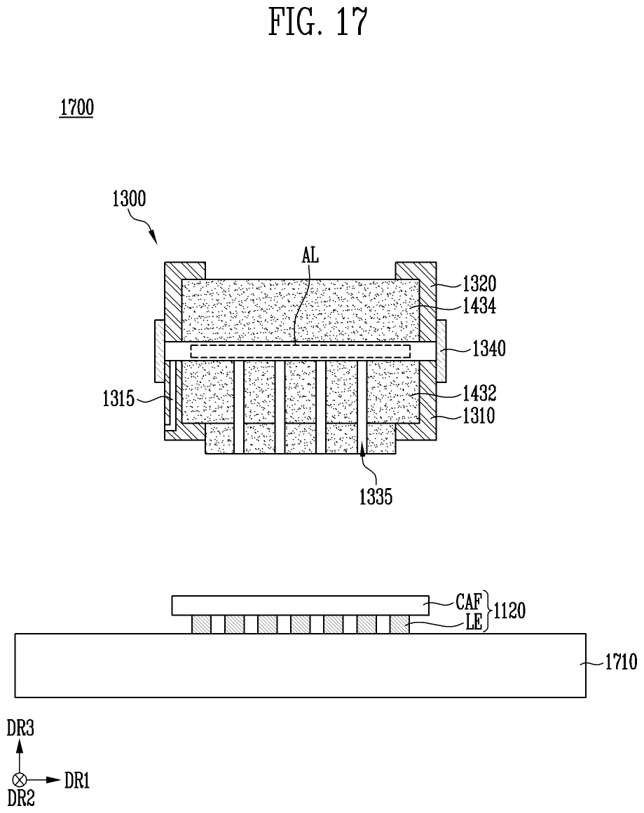

FIGS. 17 to 26 illustrate a method for driving a transfer and bonding system according to embodiments of the disclosure, respectively.

Referring to FIG. 17 to FIG. 26, the transfer and bonding system according to the embodiments of the disclosure may include a cylinder head 1300, a transfer substrate 1120, a first stage 1710, an imaging device 2110, a second stage 1810, a thin film transistor substrate 1110, and a heat source 2310.

Since descriptions of the cylinder head 1300, the transfer substrate 1120, and the thin film transistor substrate 1110 may be the same as those described above, descriptions of these components will be omitted.

The first stage 1710 may be a space in which a process of coupling the transfer substrate 1120 to the cylinder head 1300 may be performed. The cylinder head 1300 may couple to the carrier substrate CAF of the transfer substrate 1120 while being disposed on the first stage 1710. The first stage 1710 may be approximately flat, but the embodiments of the disclosure may not be limited thereto.

The second stage 1810 may be a space in which a process of transferring the transfer substrate 1120 onto the thin film transistor substrate 1110 by the cylinder head 1300 and a process of bonding the transferred transfer substrate 1120 onto the thin film transistor substrate 1110 may be performed. The second stage 1810 may be approximately flat, but the embodiments of the disclosure may not be limited thereto.

The imaging device 2110 may be configured to obtain an image of at least one of the cylinder head 1300, the transfer substrate 1120, and the thin film transistor substrate 1110. For example, the imaging device 2110 may be configured to take an image of the cylinder head 1300 and detect the position of the alignment mark 1610 from the image of the cylinder head 1300. For example, the imaging device 2110 may be configured to image the transfer substrate 1120 and obtain images of the light emitting elements LE attached to the carrier substrate CAF from the image. For example, the imaging device 2110 may be configured to image the thin film transistor substrate 1110 and detect a pattern PAT of the sub-pixels SPX from the image. The imaging device 2110 may be, for example, a camera, but the embodiments of the disclosure may not be limited thereto.

The heat source 2310 may be configured to provide heat to the transfer substrate 1120. Heat irradiated from the heat source 2310 may be provided as, for example, light in an infrared wavelength band. Heat irradiated from the heat source 2310 may be provided as, for example, a laser beam of a single wavelength band. However, the embodiments of the disclosure may not be limited thereto, and in some embodiments, light of a visible ray wavelength band or an ultraviolet wavelength band may be provided.

Referring to FIG. 17 to FIG. 26, the transfer and bonding method according to the embodiments of the disclosure may include disposing the cylinder head 1300 above the transfer substrate 1120 mounted on first stage 1710 (1700); moving the cylinder head 1300 toward the transfer substrate 1120 (1800); coupling the cylinder head 1300 to the transfer substrate 1120 (1900); moving the cylinder head 1300 coupled to the transfer substrate 1120 away from the first stage 1710 (2000); obtaining an image using an imaging device 2110 (2100); moving the cylinder head 1300 coupled to the transfer substrate 1120 towards the thin film transistor substrate 1110 (2200); applying pressure and heat to the transfer substrate 1120 (2300a and 2300b); coupling the cylinder head 1300 to the carrier substrate CAF (2400); moving the cylinder head 1300 that is coupled to the carrier substrate CAF away from the thin film transistor substrate 1110 (2500); and separating the carrier substrate CAF from the cylinder head 1300 (2600).

Referring to FIG. 17, the disposing (1700) of the cylinder head 1300 above the transfer substrate 1120 is shown. In the disposing, the cylinder head 1300 may be disposed above the transfer substrate 1120 (for example, by moving the cylinder head 1300 in a direction opposite from the third direction DR3 with respect to the transfer substrate 1120). The transfer substrate 1120 may be disposed on the first stage 1710. The position of the cylinder head 1300 may be adjusted by a cylinder (not shown) to which the cylinder head 1300 may extend.

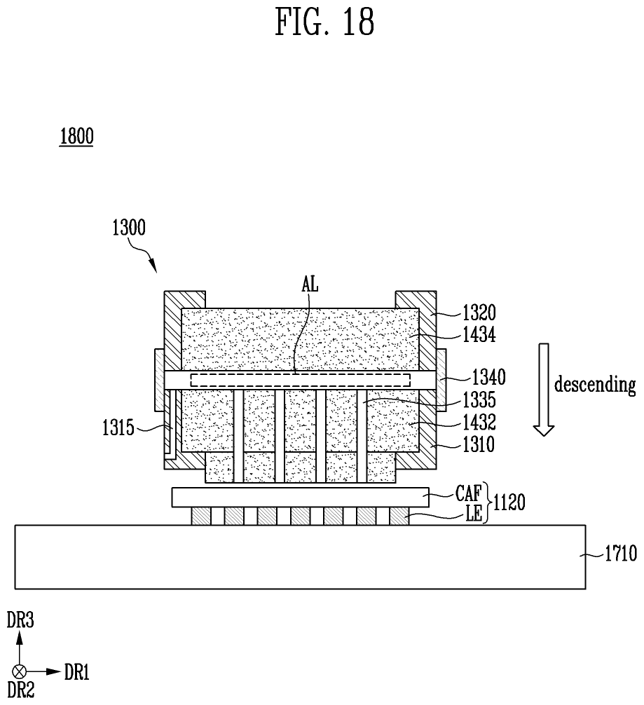

Referring to FIG. 18, the moving (1800) of the cylinder head 1300 towards transfer substrate 1120 is shown. In the moving, the cylinder head 1300 may approach the transfer substrate 1120. For example, the cylinder head 1300 may approach the transfer substrate 1120 while descending. For example, the cylinder head 1300 may approach the transfer substrate 1120 to a range of about hundreds of micrometers.

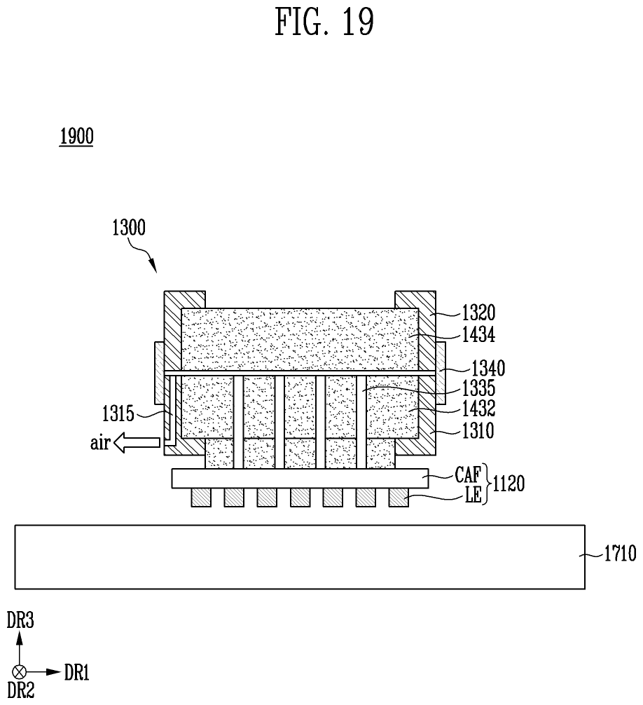

Referring to FIG. 19, the coupling (1900) of the cylinder head 1300 to the transfer substrate 1120 is shown. Air may be discharged from the inside of the cylinder head 1300 through the second air path 1315. The pressure inside the cylinder head 1300 may be lowered, and the transfer substrate 1120 (or the carrier substrate CAF) may be coupled to the cylinder head 1300. In some embodiments, the first stage 1710 may be disposed slightly inclined from the ground. Even in the above embodiment, the transfer substrate 1120 may be readily coupled to the first transmissive member 1432.

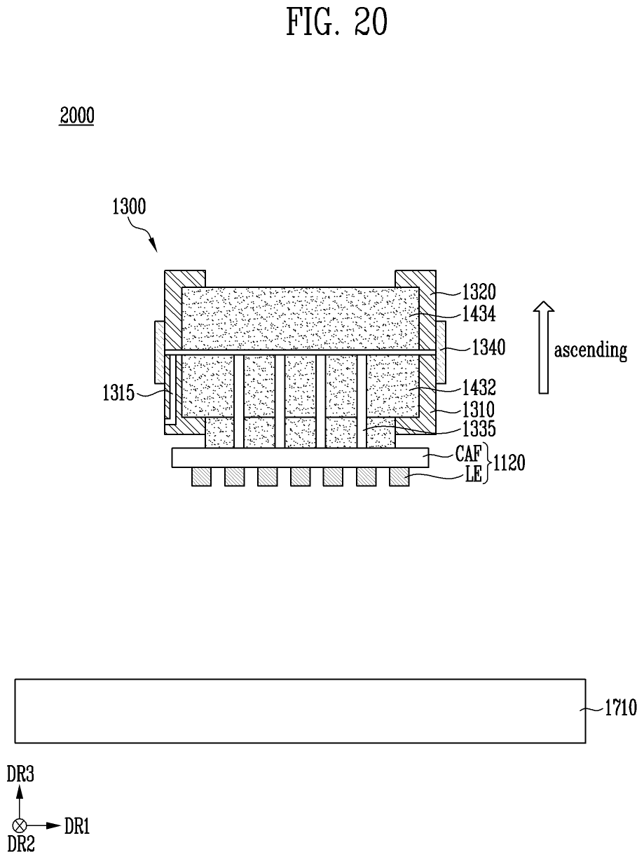

Referring to FIG. 20, the movement (2000) of the cylinder head 1300 coupled to the transfer substrate 1120 away from the first stage 1710 is shown. The cylinder head 1300 may move in a direction (for example, the third direction DR3 or an ascending direction) in a state in which the transfer substrate 1120 is coupled.

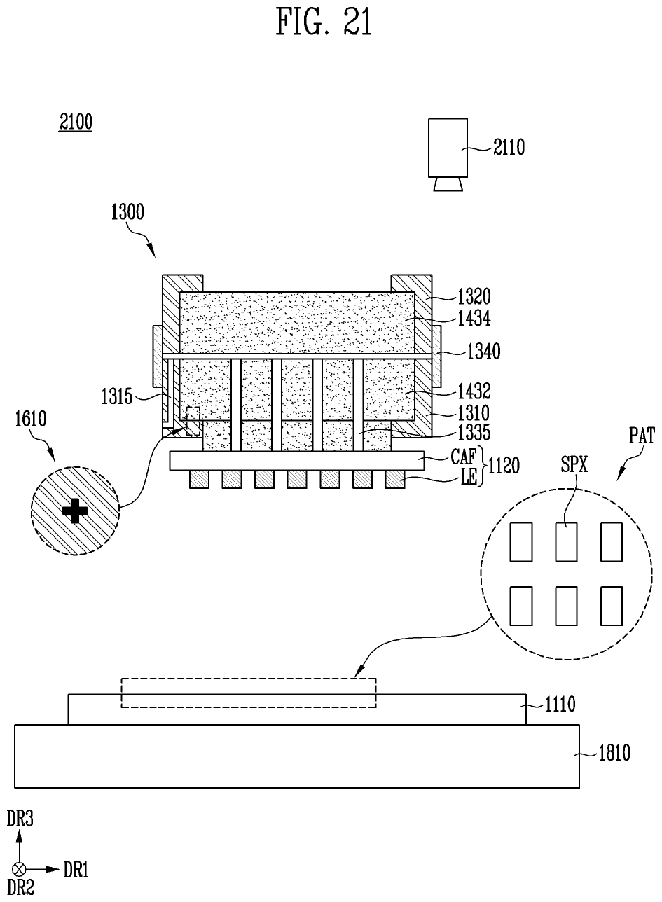

Referring to FIG. 21, the obtaining (2100) of the image using the imaging device 2110 is shown. Referring to FIG. 21, the imaging device 2110 may obtain an image of at least one of the cylinder head 1300, the carrier substrate 1120, and the thin film transistor substrate 1110. In some embodiments, the imaging device 2110 may image the cylinder head 1300 and detect the position of the alignment mark 1610 from the image. In some embodiments, the imaging device 2110 may image the transfer substrate 1120 and detect the position of the light emitting element LE coupled to the carrier substrate CAF. In some embodiments, the imaging device 2110 may image the thin film transistor substrate 1110 and detect the pattern PAT corresponding to the position of the sub-pixel SPX on the thin film transistor substrate 1110. For example, the pattern PAT corresponding to the position of the sub-pixel SPX may be formed by the thin film transistor layer TFTL described above in FIG. 9, the pixel electrode PXE of the light emitting element layer EML, and the common electrode CE. The position of the cylinder head 1300 may be precisely adjusted in first direction DR1 and/or the second direction DR2 based on the image obtained by the imaging device 2110.

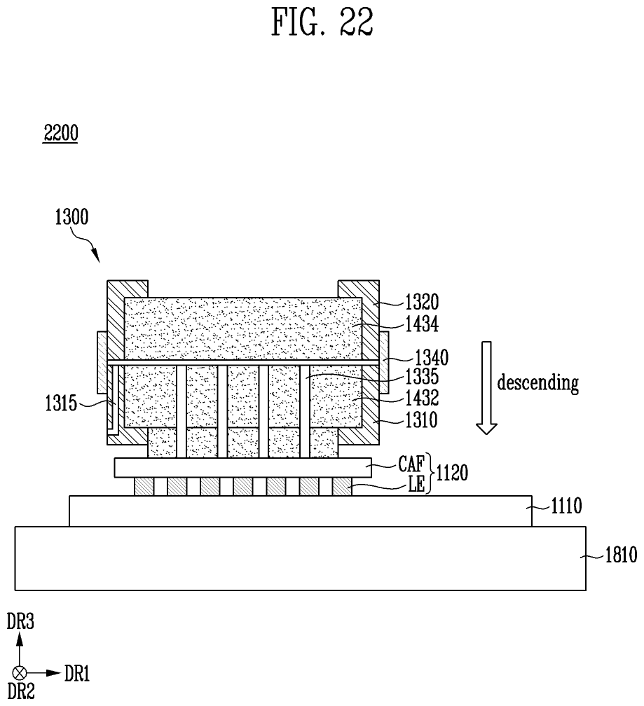

Referring to FIG. 22, the movement (2200) of the cylinder head 1300 that is coupled to the transfer substrate 1120 towards the thin film transistor substrate 1110 is shown. In the movement, the cylinder head 1300 may move (for example, descend) in a direction (for example, the minus third direction DR3). In the movement, the thin film transistor substrate 1110 and the light emitting element LE may contact each other. The steps shown in FIG. 17 to FIG. 22 may correspond to a transfer process of the light emitting element LE.

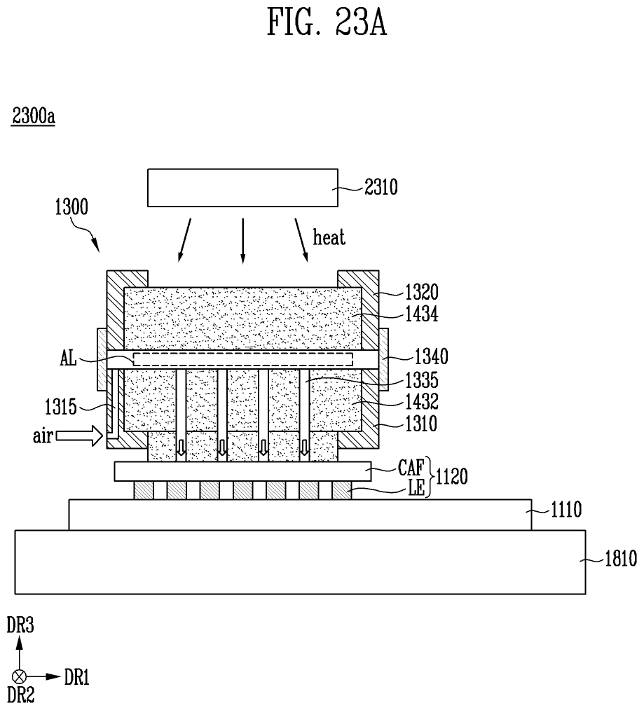

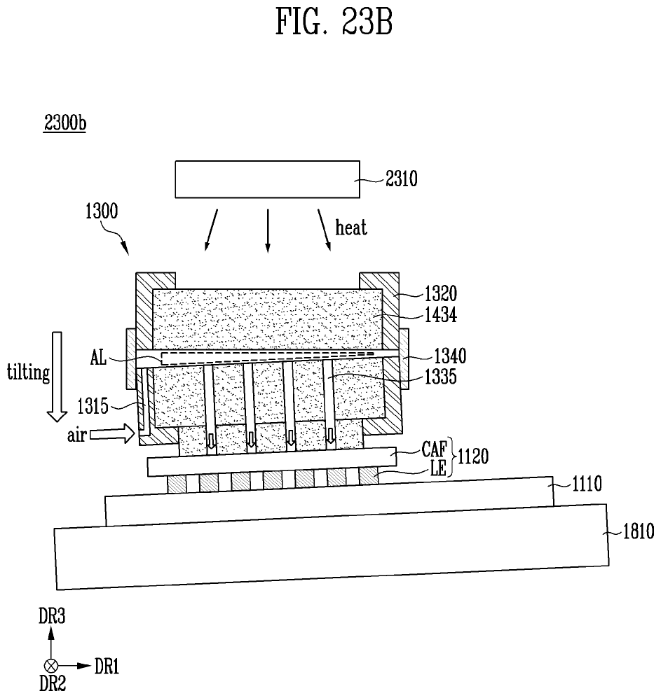

Referring to FIG. 23A and FIG. 23B, the application (2300a and 2300b) of the pressure and heat to the transfer substrate 1120 are shown. FIG. 23A shows an embodiment in which the cylinder head 1300 and the thin film transistor substrate 1110 are disposed in parallel. Hereinafter, the corresponding steps will be described with reference to FIG. 23A as a whole.

Referring to FIG. 23A, air may be injected into the second air path 1315. The second air path 1315 may extend to, for example, an air pump (not shown). Air supplied from the air pump may be injected into the second air path 1315. The air layer AL may be provided between the first bracket 1310 and the second bracket 1320. The air injected through the second air path 1315 may be stored in the air layer AL. The air layer AL may provide pressure to the first transmissive member 1432, and the first transmissive member 1432 may provide pressure to the light emitting element LE through the carrier substrate CAF.

Referring to FIG. 23A, the heat source 2310 may provide heat. At least a portion of the provided heat may pass through the second transmissive member 1434, the air layer AL, the first transmissive member 1432, and the carrier substrate CAF to reach the light emitting element LE. Through this, heat may be provided to the light emitting element LE. The light emitting element LE may be fixed to the thin film transistor substrate 1110 by receiving pressure and heat. The steps shown in FIG. 23A and FIG. 23B may correspond to a bonding process of the light emitting element LE.

FIG. 23B shows an embodiment in which the cylinder head 1300 and the thin film transistor substrate 1110 may be inclined and disposed. In the above embodiment, the thin film transistor substrate 1110 may be disposed to be inclined from the ground together with the second stage 1810. Referring to FIG. 23B, the shape of the air layer AL may be fluidly changed according to the position of the thin film transistor substrate 1110. The air layer AL may uniformly provide pressure to the first transmissive member 1432 as a whole. Accordingly, the first transmissive member 1432 may provide pressure (for example, uniform pressure) to the light emitting element LE through the carrier substrate CAF.

In the corresponding step, the light emitting element LE may be bonded to the thin film transistor substrate 1110. In the corresponding step, the bonding force between the light emitting element LE and the thin film transistor substrate 1110 may be greater than the bonding force between the light emitting element LE and the carrier substrate CAF.

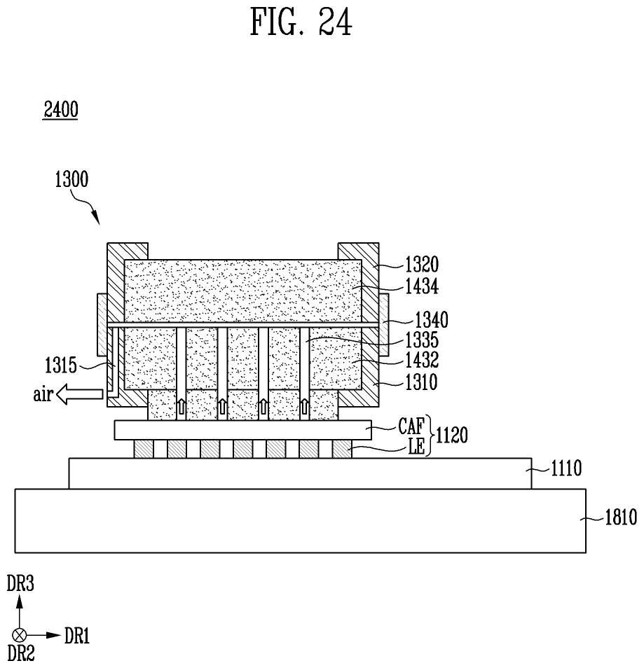

Referring to FIG. 24, the coupling (2400) of the cylinder head 1300 to the carrier substrate CAF may be shown. In the corresponding step, air may be discharged through the second air path 1315. The carrier substrate CAF may be attached to the first transmissive member 1432. Since the bonding force between the light emitting element LE and the thin film transistor substrate 1110 may be greater than the bonding force between the light emitting element LE and the carrier substrate CAF, in the corresponding step, the light emitting element LE and the carrier substrate CAF may be separated from each other.

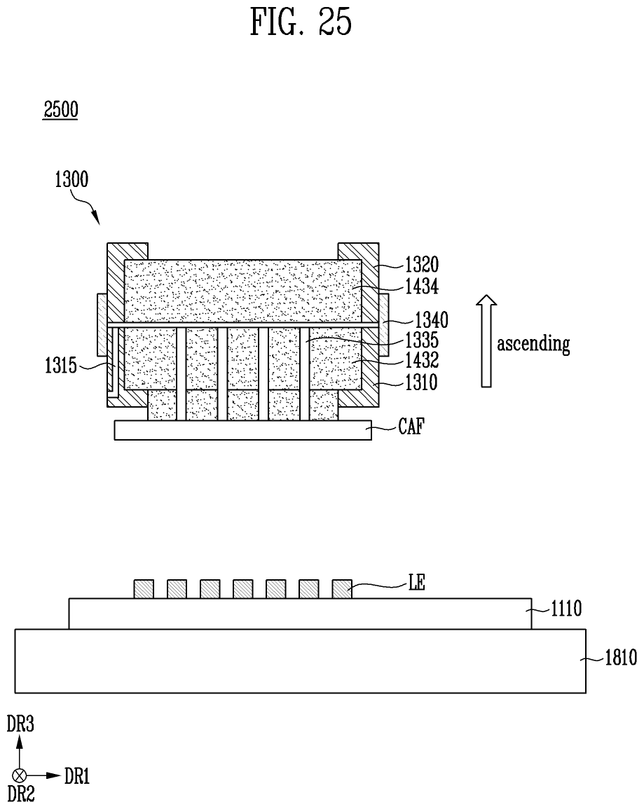

Referring to FIG. 25, the movement (2500) of the cylinder head 1300 coupled to the carrier substrate CAF is shown. In the movement, the cylinder head 1300 coupled to the carrier substrate CAF may move (for example, ascend) in a direction (for example, the third direction DR3) away from the second stage 1810. In the movement, the light emitting element LE may remain bonded to the thin film transistor substrate 1110 disposed on second stage 1810.

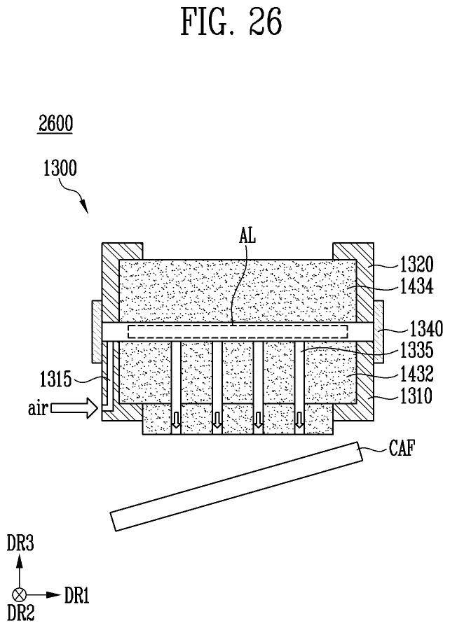

Referring to FIG. 26, the separating (2600) of the carrier substrate CAF from the cylinder head 1300 is shown. In the separating, air may be injected into the second air path 1315. The bonding force between the first transmissive member 1432 and the carrier substrate CAF may be weakened, and the carrier substrate CAF may be separated from the first transmissive member 1432.

The steps described with reference to FIG. 17 to FIG. 26 may be repeatedly performed. Through this, the transfer and bonding process may be repeatedly performed on the thin film transistor substrate 1110. Accordingly, the light emitting elements LE may be effectively transferred to the large-area thin film transistor substrate 1110 and the transferred light emitting elements LE may be effectively bonded.

According to the cylinder head, the transfer and bonding system including the same, and the method for driving the same according to the embodiments of the disclosure, it may be possible to provide uniform pressure to a light emitting element during a transfer and bonding process of a light emitting element.

While this disclosure has been described in connection with what may be presently considered to be practical embodiments, it may be to be understood that the disclosure may not be limited to the disclosed embodiments, but, on the contrary, may be intended to cover various modifications and equivalent arrangements included within the spirit and scope of the appended claims. Therefore, those skilled in the art will understand that various modifications and other equivalent embodiments of the disclosure may be possible. Consequently, the true technical protective scope of the disclosure must be determined based on the technical spirit of the appended claims.

What is claimed is:

1. A cylinder head comprising:
a first transmissive portion including at least one first air path extending to an air layer;
a first bracket accommodating the first transmissive portion;
a second transmissive portion spaced apart from the first transmissive portion in a direction by the air layer;
a second bracket accommodating the second transmissive portion; and
an elastic member surrounding side surfaces of the first bracket and the second bracket,
wherein one of the first bracket and the second bracket includes a second air path extending to the air layer.

2. The cylinder head of claim 1, wherein the elastic member stretches in the direction in case that air is introduced through the second air path.

3. The cylinder head of claim 1, wherein the elastic member contracts in the direction in case that air is expelled from the cylinder head through the second air path.

4. The cylinder head of claim 1, further comprising:
a first fastening portion configured to surround the elastic member and to fix the elastic member to a side surface of the first bracket; and
a second fastening portion configured to surround the elastic member and to fix the elastic member to a side surface of the second bracket.

5. The cylinder head of claim 1, further comprising:
a first buffer member disposed between the first transmissive portion and the first bracket and surrounding a side surface of the first transmissive portion; and
a second buffer member disposed between the second transmissive portion and the second bracket and surrounding a side surface of the second transmissive portion.

6. The cylinder head of claim 1, wherein the first bracket comprises an alignment mark that overlaps the first transmissive portion and the second transmissive portion.

7. The cylinder head of claim 1, wherein a volume of the air layer varies.

8. The cylinder head of claim 1, wherein
the at least one first air path includes a plurality of first air paths, and
the plurality of first air paths are arranged in a lattice form.

9. The cylinder head of claim 1, wherein the second air path extends to an air pump configured to inject or discharge air.

10. A transfer and bonding system, comprising:
a cylinder head;
an imaging device configured to obtain an image in a direction; and
a heat source configured to apply heat to the cylinder head, wherein
the cylinder head includes:
a first transmissive portion including a first air path extending to an air layer;
a first bracket accommodating the first transmissive portion;
a second transmissive portion spaced apart from the first transmissive portion in the direction by the air layer;
a second bracket accommodating the second transmissive portion; and
an elastic member surrounding side surfaces of the first bracket and the second bracket, and
one of the first bracket and the second bracket includes a second air path extending to the air layer.

11. The transfer and bonding system of claim 10, further comprising a transfer substrate that comprises:
a carrier substrate; and
a plurality of light emitting elements coupled to the carrier substrate, wherein the carrier substrate is in contact with the first transmissive portion.

12. The transfer and bonding system of claim 11, further comprising:
a thin film transistor substrate including a thin film transistor layer, wherein
a position of the cylinder head is adjusted based on the image obtained by the imaging device of a pattern of the thin film transistor substrate.

13. The transfer and bonding system of claim 11, wherein
the first bracket includes an alignment mark that overlaps the first transmissive portion and the second transmissive portion, and
a position of the cylinder head is adjusted based on the image obtained by the imaging device of the alignment mark.

14. The transfer and bonding system of claim 11, wherein
the carrier substrate is coupled to the cylinder head in case that air is discharged from the second air path to an outside; and
the carrier substrate is separated from the cylinder head in case that air is introduced into the second air path from an outside.

15. The transfer and bonding system of claim 10, wherein the heat source irradiates a laser onto the first transmissive portion and the second transmissive portion.

16. A driving method, comprising:
providing a cylinder head comprising:
a first transmissive portion including a first air path extending to an air layer;
a first bracket accommodating the first transmissive portion;
a second transmissive portion spaced apart from the first transmissive portion in a direction by the air layer;
a second bracket accommodating the second transmissive portion; and
an elastic member surrounding side surfaces of the first bracket and the second bracket, and
one of the first bracket and the second bracket includes a second air path extending to the air layer;
providing a transfer substrate that includes a carrier substrate coupled to a plurality of light emitting elements;
providing a thin film transistor substrate that includes a thin film transistor layer;
moving the cylinder head towards the transfer substrate;
discharging air from the cylinder head through the second air path to couple the transfer substrate to the first transmissive portion of the cylinder head;
moving the cylinder head that is coupled to the transfer substrate towards a thin film transistor substrate;
injecting air into the cylinder head through the second air path to press the first transmissive portion of the cylinder head against the transfer substrate;
discharging the air from the cylinder head through the second air path to couple the carrier substrate to the first transmissive portion of the cylinder head; and
injecting the air into the cylinder head via the second air path to separate the carrier substrate from the first transmissive portion of the cylinder head.

17. The driving method of claim 16, wherein the moving of the cylinder head that is coupled to the transfer substrate towards the thin film transistor substrate includes:
obtaining an image of the thin film transistor substrate;
detecting a pattern in the thin film transistor substrate from the image; and
adjusting a position of the cylinder head based on the detected pattern.

18. The driving method of claim 16, wherein the moving of the cylinder head coupled to the transfer substrate towards the thin film transistor substrate includes:
obtaining an image of an alignment mark of the cylinder head; and
adjusting a position of the cylinder head based on the image.

19. The driving method of claim 16, wherein the plurality of light emitting elements are micro light emitting diodes.

20. The driving method of claim 16, wherein the injecting of the air into the cylinder head to press the first transmissive portion of the cylinder head against the transfer substrate comprises irradiating the thin film transistor substrate with a laser that transmits through the first transmissive portion and the second transmissive portion.
